(19) United States
(12) Patent Application Publication
(10) Pub. No.: US 2024/0206290 A1
(43) Pub. Date: Jun. 20, 2024

(54) DISPLAY PANEL AND MANUFACTURING METHOD THEREOF

(71) Applicant: Samsung Display Co., Ltd., Yongin-si (KR)

(72) Inventor: JINHO JU, Yongin-si (KR)

(73) Assignee: Samsung Display Co., Ltd., Yongin-si (KR)

(21) Appl. No.: 18/535,237

(22) Filed: Dec. 11, 2023

(30) Foreign Application Priority Data
Dec. 12, 2022 (KR) 10-2022-0173088

(51) Int. Cl. H10K 59/80; H10K 59/12; H10K 59/122; H10K 59/123; H10K 59/131; H10K 59/88

(52) U.S. Cl. CPC H10K 59/877; H10K 59/1201; H10K 59/122; H10K 59/123; H10K 59/131; H10K 59/873; H10K 59/88

(57) ABSTRACT

A display panel includes a base layer, a transistor on the base layer, a pixel definition layer disposed on an upper insulation layer and including an emission opening, a light emitting element disposed on the upper insulation layer and including a first electrode, a second electrode disposed on the first electrode, and a light emitting layer disposed between the first electrode and the second electrode, and a separator disposed on the pixel definition layer and including a first surface adjacent to the pixel definition layer and a second surface facing the first surface, and having a width increasing as being closer to the second surface from the first surface. The second electrode is electrically connected to the transistor, and the separator includes a base resin and a scattering agent.

### CROSS-REFERENCE TO RELATED APPLICATION(S)

This application claims priority to and benefits of Korean Patent Application No. 10-2022-0173088 under 35 U.S.C. § 119, filed on Dec. 12, 2022, the entire contents of which are incorporated herein by reference.

### BACKGROUND

Embodiments relate to a display panel including a separator and a manufacturing method of the display panel.

### 2. Description of the Related Art

A multi-media electronic device such as a television, a mobile phone, a tablet, a computer, a navigator, a game player or the like includes a display panel for displaying an image.

The display panel includes light emitting elements and a circuit for controlling the light emitting elements. The light emitting elements included in the display panel emit light and generate an image according to voltages applied from the circuit. In order to improve the reliability of the display panel, the connection between the light emitting elements and the circuit has been researched and developed.

### SUMMARY

Embodiments provide a display panel capable of improving reliability.

Embodiments also provide a manufacturing method of the display panel by simplified processes.

However, embodiments of the disclosure are not limited to those set forth herein. The above and other embodiments will become more apparent to one of ordinary skill in the art to which the disclosure pertains by referencing the detailed description of the disclosure given below.

In an embodiment, a display panel including a display area and a peripheral area adjacent to the display area may include: a base layer; first and second transistors on the base layer; an upper insulation layer on the first and second transistors; a pixel definition layer disposed on the upper insulation layer and including an emission opening; each of first and second light emitting elements disposed on the upper insulation layer and including a first electrode disposed in the emission opening, a second electrode disposed on the first electrode, and a light emitting layer disposed between the first electrode and the second electrode; and a separator disposed between the second electrode of the first light emitting element and the second electrode of the second light emitting element, disposed on the pixel definition layer, and including a first surface adjacent to the pixel definition layer and a second surface facing the first surface, and having a width increasing as being closer to the second surface from the first surface, wherein the second electrode of the first light emitting element may be electrically connected to the first transistor, the second electrode of the second light emitting element may be electrically connected to the second transistor, and the separator may include a base resin and a scattering agent.

In an embodiment, the scattering agent may include at least one of TiO₂, ZnO, Al₂O₃, SiO₂, and hollow silica.

In an embodiment, the separator may include the scattering agent having an amount of about 8 wt % to about 11 wt %, based on a total weight of the separator.

In an embodiment, the display panel may further include a connection line disposed under the upper insulation layer and electrically connecting the first transistor and the second electrode of the first light emitting element.

In an embodiment, the display panel may further include a lower insulation layer between the first transistor and the connection line, wherein the first transistor and the connection line are connected through a contact hole passing through the lower insulation layer.

In an embodiment, the connection line may include: a first layer; a second layer disposed on the first layer; and a third layer disposed on the second layer, the third layer and the first layer including a same material, wherein an edge portion of each of the first and third layers may protrude from an edge portion of the second layer, and the second electrode of the first light emitting element may contact a side surface of the second layer of the connection line.

In an embodiment, the display panel may further include a power line receiving a constant voltage and overlapping the peripheral area, wherein the first electrode may be electrically connected to the power line.

In an embodiment, a display panel includes: a base layer; a pixel definition layer disposed on the base layer and including an emission opening; each of first and second light emitting elements disposed on an upper insulation layer and including a first electrode disposed in the emission opening, a second electrode disposed on the first electrode, and a light emitting layer disposed between the first electrode and the second electrode; a separator disposed between the second electrode of the first light emitting element and the second electrode of the second light emitting element, disposed on the pixel definition layer, and including a first surface adjacent to the pixel definition layer and a second surface facing the first surface, and having a width increasing as being closer to the second surface from the first surface; and an encapsulation layer covering the separator, wherein the separator may include a base resin, and a scattering agent.

In an embodiment, the scattering agent may include at least one of TiO₂, ZnO, Al₂O₃, SiO₂, and hollow silica.

In an embodiment, the separator may include: a first sub-separator adjacent to the first light emitting element; and a second sub-separator spaced apart from the first sub-separator and adjacent to the second light emitting element, and the encapsulation layer may cover each of the first sub-separator and the second sub-separator.

In an embodiment, the encapsulation layer may include: a first inorganic layer adjacent to the second electrode; a second inorganic layer disposed on the first inorganic layer; and an organic layer disposed between the first inorganic layer and the second inorganic layer.

In an embodiment, the first inorganic layer may extend along a shape of each of the first sub-separator and the second sub-separator, and the organic layer may may be disposed between the first and second sub-separators.

In an embodiment, the display panel may further include a lower dummy layer disposed between the first sub-separator and the second sub-separator, disposed on the pixel definition layer, and covered by the organic layer.

In an embodiment, a manufacturing method of a display panel may include: providing a preliminary display panel including a base layer, first and second transistors disposed on the base layer, an insulation layer disposed on the first and second transistors, a pixel definition layer disposed on the insulation layer and including an opening, and a first electrode disposed in the opening of the pixel definition layer; applying a photosensitive organic composition including a base resin and a scattering agent on the pixel definition layer; disposing a mask including a mask opening on the photosensitive organic composition; forming a separator by irradiating light on the photosensitive organic composition through the mask opening to cure a portion of the photosensitive organic composition; and forming a light emitting layer and a second electrode on the separator and the preliminary display panel, wherein the second electrode disposed on the separator and the second electrode disposed on the first electrode may be separated from each other.

In an embodiment, the scattering agent may include at least one of TiO₂, ZnO, Al₂O₃, SiO₂, and hollow silica.

In an embodiment, the photosensitive organic composition may include the scattering agent having an amount of about 8 wt % to about 11 wt %, based on a total weight of the photosensitive organic composition.

In an embodiment, the photosensitive organic composition may further include at least one of a photosensitive compound, a coupling agent, a crosslinker, a solvent, and a surfactant.

In an embodiment, the photosensitive organic composition may include about 8 wt % to about 11 wt % of the scattering agent, based on a total weight of the photosensitive organic composition.

In an embodiment, the separator may include a first surface adjacent to the pixel definition layer and a second surface facing the first surface, and a width of the separator increases as being closer to the second surface from the first surface.

In an embodiment, the forming of the separator may include: irradiating light on the photosensitive organic composition; and developing the photosensitive organic composition irradiated with light.

In an embodiment, the forming of the separator may not include heating the photosensitive organic composition irradiated with light between the irradiating of the light on the photosensitive organic composition and the developing of the photosensitive organic composition irradiated with light.

### BRIEF DESCRIPTION OF THE DRAWINGS

The accompanying drawings are included to provide a further understanding of the invention, and are incorporated in and constitute a part of the disclosure. The drawings illustrate embodiments and, together with the description, serve to explain principles of the invention. In the drawings:

FIG. 1 is a block diagram of a display device according to an embodiment;

FIG. 2A is a schematic diagram of an equivalent circuit of a pixel according to an embodiment;

FIG. 2B is a schematic diagram of an equivalent circuit of a pixel according to an embodiment;

FIG. 3A is a schematic plan view of a display panel according to an embodiment;

FIG. 3B is a schematic plan view of a display panel according to an embodiment;

FIG. 4A is an enlarged schematic plan view of a portion of a display panel according to an embodiment;

FIG. 4B is an enlarged schematic plan view of a portion of a display panel according to an embodiment;

FIG. 4C is an enlarged schematic plan view of a portion of a display panel according to an embodiment;

FIG. 5 is a schematic cross-sectional view of a display panel according to an embodiment.

FIG. 6A is an enlarged schematic cross-sectional view of a portion of a display panel according to an embodiment.

FIG. 6B is an enlarged schematic cross-sectional view of a portion of a display panel according to an embodiment.

FIG. 7 is a schematic cross-sectional view of a display panel according to an embodiment;

FIG. 8 is an enlarged schematic plan view of a portion of a display panel according to an embodiment;

FIG. 9 is a schematic cross-sectional view of a display panel according to an embodiment;

FIG. 10 is a flowchart of a manufacturing method of a display panel according to an embodiment;

FIG. 11 is a flowchart showing a step of a manufacturing method of a display panel according to an embodiment;

FIG. 12A schematically shows a step of a manufacturing method of a display panel according to an embodiment;

FIG. 12B schematically shows a step of a manufacturing method of a display panel according to an embodiment;

FIG. 12C schematically shows a step of a manufacturing method of a display panel according to an embodiment;

FIG. 12D schematically shows a step of a manufacturing method of a display panel according to an embodiment;

FIG. 13A shows the shape of a separator according to an embodiment;

FIG. 13B shows the shape of a separator according to an embodiment;

FIG. 13C shows the shape of a separator according to a comparative example; and

FIG. 13D shows the shape of a separator according to a comparative example.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, the invention will be explained with reference to the accompanying drawings.

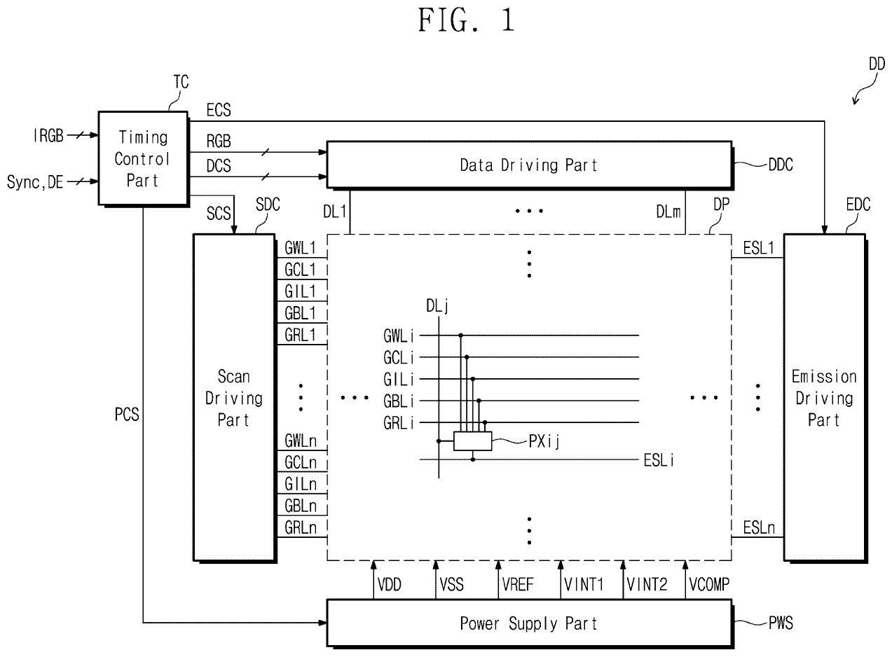

FIG. 1 is a block diagram of a display device DD according to an embodiment. With reference to FIG. 1, the display device DD may include a display panel DP, a panel driving part (e.g., SDC, EDC, and DDC), a power supply part PWS, and a timing control part TC. In an embodiment, the display panel DP will be described as an emissive display panel. The emissive display panel may include an organic light emitting display panel, an inorganic light emitting display panel, or a quantum dot light emitting display panel. In an embodiment to be described below, the organic light emitting display panel will be described as an example. The panel driving part may include a scan driving part SDC, an emission driving part EDC, and a data driving part DDC.

The display panel DP may include scan lines GWL1 to GWLn, GCL1 to GCLn, GIL1 to GILn, GBL1 to GBLn, GRL1 to GRLn, emission lines ESL1 and ESLn, and data lines DL1 to DLm. The display panel DP may include pixels connected to the scan lines GWL1 to GWLn, GCL1 to GCLn, GIL1 to GILn, GBL1 to GBLn, GRL1 to GRLn, the emission lines ESL1 to ESLn, and the data lines DL1 to DLm. Here, m and n are integers greater than 1.

For example, a pixel PXij positioned at an i-th horizontal line (or an i-th pixel row) and a j-th vertical line (or a j-th pixel column) may be connected to an i-th first scan line (or a write scan line GWLi), an i-th second scan line (or a compensation scan line GCLi), an i-th third scan line (or a first initialization scan line GILi), an i-th fourth scan line (or a second initialization scan line GBLi), an i-th fifth scan line (or a reset scan line GRLi), a j-th data line DLj, and an i-th emission line ESLi (hereinafter, an emission line)). Here, i and j are integers greater than 1.

The pixel PXij may include light emitting elements, transistors, and capacitors. The pixel PXij may receive, through the power supply part PWS, a first power supply voltage VDD, a second power supply voltage VSS, a third power supply voltage (or a reference voltage) VREF, a fourth power supply voltage (or a first initialization voltage) VINT1, a fifth power supply voltage (or a second initialization voltage) VINT2, and a sixth power supply voltage (or a compensation voltage) VCOMP.

For the first power supply voltage VDD and the second power supply voltage VSS, the values thereof may be set so that a current may flow to, and may cause the light emitting element to emit light. For example, the first power supply voltage VDD may be set higher than the second power supply voltage VSS.

The third power supply voltage VREF may be a voltage to initialize a gate of a driving transistor included in the pixel PXij. The third power supply voltage VREF may be used to implement a certain gradation by using a voltage difference with that of a data signal. For example, the third power supply voltage VREF may be set to a certain voltage within a voltage range of the data signal.

The fourth power supply voltage VINT1 may be a voltage to initialize the capacitors included in the pixel PXij. The fourth power supply voltage VINT1 may be set lower than the third power supply voltage VREF. For example, the fourth power supply voltage VINT1 may be set to a voltage lower than a threshold voltage difference between the third power supply voltage VREF and the driving transistor. However, embodiments are not limited thereto.

The fifth power supply voltage VINT2 may be a voltage to initialize a cathode of the light emitting element included in the pixel PXij. The fifth power supply voltage VINT2 may be set to a voltage lower than the first power supply voltage VDD or the fourth power supply voltage VINT1, or set to a voltage similar or identical to the third power supply voltage VREF, but embodiments are not limited thereto. The fifth power supply voltage VINT2 may be set to a voltage similar or identical to the first power supply voltage VDD.

The sixth power supply voltage VCOMP may supply a certain current to the driving transistor in case that the threshold voltage of the driving transistor is compensated.

In FIG. 1, the first to sixth power supply voltages VDD, VSS, VREF, VINT1, VINT2, and VCOMP are all shown as supplied by the power supply part PWS, but embodiments are not limited thereto. For example, the first power supply voltage VDD and the second power supply voltage VSS may be supplied regardless of the structure of the pixel PXij, but at least one of the third power supply voltage VREF, the fourth power supply voltage VINT1, the fifth power supply voltage VINT2, or the sixth power supply voltage VCOMP may not be supplied in correspondence to the structure of the pixel PXij.

In an embodiment, signal lines connected to the pixel PXij may be set in various ways in correspondence to the circuit structure of the pixel PXij.

The scan driving part SDC may receive a first control signal SCS from the timing control part TC, and supply, based on the first control signal SCS, scan signals to the first scan lines GWL1 to GWLn, the second scan lines GCL1 to GCLn, the third scan lines GIL1 to GILn, fourth scan lines GBL1 to GBLn, or the fifth scan lines GRL1 to GRLn.

The scan signal may be set to a voltage by which the transistor supplied with the scan signals may be turned on. For example, a scan signal to be supplied to a P-type transistor may be set to a logic low level, and a scan signal to be supplied to an N-type transistor may be set to a logic high level. Hereinafter, “that a scan signal is supplied” may be understood as that the scan signal is supplied as a logic level signal to turn on a transistor controlled by the scan signal. For convenience of explanation, FIG. 1 shows that the scan driving part SDC has a single component, but embodiments are not limited thereto. According to an embodiment, scan driving parts may be included to supply the scan signals to the first scan lines GWL1 to GWLn, the second scan lines GCL1 to GCLn, the third scan lines GIL1 to GILn, fourth scan lines GBL1 to GBLn, or the fifth scan lines GRL1 to GRLn.

The emission driving part EDC may output an emission control signal to the emission lines ESL1 to ESLn based on a second control signal ECS. For example, the emission control signal may be sequentially supplied to the emission lines ESL1 to ESLn.

The transistors connected to the emission lines ESL1 to ESLn according to an embodiment may be formed as N-type transistors. For example, the emission signal supplied to the emission lines ESL1 to ESLn may be set to a gate-off voltage. The transistors that receive the emission signal may be set to be turned off, in case that the emission signal is supplied, and to be in a turned-on state, otherwise.

The second control signals ECS may include an emission start signal and clock signals, and the emission driving part EDC may be implemented by a shift register that sequentially shift an emission start signal of a pulse type by using the clock signals to sequentially generate and output the emission signal in a pulse type.

The data driving part DDC may receive a third control signal DCS and image data RGB from the timing control part TC. The data driving part DDC may convert the digital image data RGB into an analog data signal (or a data signal). The data driving part DDC may supply the data signal to the data lines DL1 to DLm in response to the third control signal DCS.

The third control signal DCS may include a data enable signal, a horizontal start signal, a data clock signal or the like for instructing to output a valid data signal. For example, the data driving part DDC may include a shift register that shifts the horizontal start signal, which is synchronized with the data clock signal to generate a sampling signal, a latch that latches the image data RGB in response to the sampling signal, an digital-to-analog converter (or a decoder) that converts the latched image data (e.g., digital-type data) to analog data signals, and buffers (or amplifiers) that output the data signals to the data lines DL1 to DLm.

The power supply part PWS may supply, to the display panel DP, the first power supply voltage VDD, the second power supply voltage VSS, or the third power supply voltage VREF for driving the pixel PXij. For example, the power supply part PWS may supply, to the display panel DP, at least one of the fourth power supply voltage VINT1, the fifth power supply voltage VINT2, or the sixth power supply voltage VCOMP.

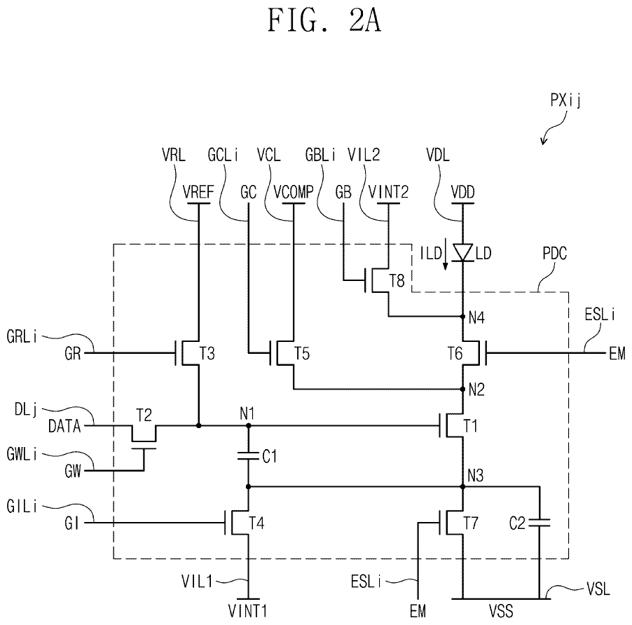

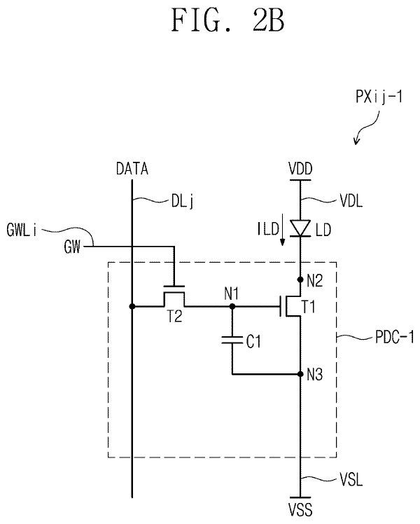

For example, the power supply part PWS may supply, to the display panel DP, the first power supply voltage VDD, the second power supply voltage VSS, the third power supply voltage VREF, the fourth power supply voltage VINT1, the fifth power supply voltage VINT2, or the sixth power supply voltage VCOMP via a first power line VDL (see FIG. 2A), a second power line VSL (see FIG. 2A), a third power line VRL (or a reference voltage line, see FIG. 2A), a fourth power line VIL1 (or a first initialization voltage line, see FIG. 2A), a fifth power line VIL2 (or a second initialization voltage line, see FIG. 2A), and a sixth power line VCL (or a compensation voltage line, see FIG. 2A).

The power supply part PWS may be implemented as a power management integrated circuit, but embodiments are not limited thereto.

The timing control part TC may generate the first control signal SCS, the second control signal ECS, the third control signal DCS, and a fourth control signal PCS based on input image data IRGB, a sync signal Sync (e.g., a vertical sync signal and a horizontal sync signal, etc.), the data enable signal DE, the clock signal or the like. The first control signal SCS may be supplied to the scan driving part SDC, the second control signal ECS to the emission driving part EDC, the third control signal DCS to the data driving part DDC, and the fourth control signal PCS to the power supply part PWS. The timing control part TC may rearrange the input image data IRGB in correspondence to the arrangement of the pixels PXij in the display panel DP to generate the image data RGB (or frame data).

For example, the scan driving part SDC, the emission driving part EDC, the data driving part DDC, the power supply part PWS, and/or the timing control part TC may be provided (e.g., directly provided) in the display panel DP, or provided in a separate driving chip type to be connected to the display panel DP. For example, at least two of the scan driving part SDC, the emission driving part EDC, the data driving part DDC, the power supply part PWS, or the timing control part TC may be provided in a driving chip (e.g., a single driving chip). For example, the data driving part DDC and the timing control part TC may be provided as a driving chip (e.g., a single driving chip).

While the display device DD according to an embodiment is described so far with reference to FIG. 1, embodiments are not limited thereto. Signal lines may be further added or omitted according to the configuration of the pixel. For example, the connection relationship between a pixel (e.g., single pixel) and the signal lines may also change. In case that any one of the signal lines is omitted, the omitted signal line may be replaced with another signal line.

FIGS. 2A and 2B are schematic diagrams of equivalent circuit of a pixel according to an embodiment. FIGS. 2A and 2B show examples of equivalent circuits of pixels PXij and PXij-1 connected to the i-th first scan line GWLi (hereinafter, a first scan line) and the j-th data line DLj (hereinafter, a data line).

As shown in FIG. 2A, the pixel PXij may include a light emitting element LD and a pixel driving part PDC. The light emitting element LD may be connected to the first power line VDL and the pixel driving part PDC.

The pixel driving part PDC may be connected to the scan lines GWLi, GCLi, GBLi, GILi, GRLi, the data line DLj, an emission line ESLi, and the power supply lines VDL, VSL, VIL1, VIL2, VRL, and VCL. The pixel driving part PDC may include first to eighth transistors T1, T2, T3, T4, T5, T6, T7, and T8, a first capacitor C1 and the second capacitor C2. Hereinafter, each of the first to eighth transistors T1, T2, T3, T4, T5, T6, T7, and T8 will be described as, for example, an N-type transistor. However, embodiments are not limited thereto, and some of the first to eighth transistors T1 to T8 may be N-type transistors, and the others may be P-type transistors. In another example, each of the first to eighth transistors T1 to T8 may be a P-type transistor, but embodiments are not limited thereto.

A gate of the first transistor T1 may be connected to a first node N1. A first electrode of the first transistor T1 may be connected to a second node N2, and a second electrode of the first transistor T1 may be connected to the third node N3. The first transistor T1 may be a driving transistor. The first transistor T1 may control a driving current ILD flowing to the second power line VSL via the light emitting element LD from the first power line VDL in response to a voltage of the first node N1. For example, the first power supply voltage VDD may be set to have a higher potential than the second power supply voltage VSS.

The expression “being electrically connected between a transistor and a signal line or between a transistor and another transistor” disclosed herein means that “a source, a drain, and a gate of the transistor have an integrated shape with the signal line or are connected through connection electrodes”.

The second transistor T2 may include a gate connected to the write scan line GWLi, a first electrode connected to the data line DLj, and a second electrode connected to the first node N1. The second transistor T2 may supply a data signal DATA to the first node N1 in response to a write scan signal GW transferred through the write scan line GWLi. In case that the write scan signal GW is supplied to the write scan line GWLi, the second transistor T2 may be turned on to connect the data line DLj and the first node N1.

The third transistor T3 may be connected between the first node N1 and the reference voltage line VRL. A first electrode of the third transistor T3 may receive the reference voltage VREF through the reference voltage line VRL, and a second electrode of the third transistor T3 may be connected to the first node N1. In an embodiment, a gate of the third transistor T3 may receive a reset scan signal GR through the i-th fifth scan line GRLi (hereafter, a reset scan line). In case that the reset scan signal GR is supplied to the reset scan line GRLi, the third transistor T3 may be supply the reference voltage VREF to the first node N1.

The fourth transistor T4 may be connected between the third node N3 and the initialization voltage line VIL1. A first electrode of the fourth transistor T4 may be connected to the third node N3, and a second electrode of the fourth transistor T4 may be connected to the first initialization voltage line VIL1 through which the first initialization voltage VINT1 is supplied. The fourth transistor T4 may be referred to as a first initialization transistor. A gate of the fourth transistor T4 may receive a first initialization scan signal GI through the i-th third scan line GILi. In case that the first initialization scan signal GI is supplied to the first initialization scan line GILi, the fourth transistor T4 may be turned on to supply the first initialization voltage VINT1 to the third node N3.

The fifth transistor T5 may be connected between the compensation voltage line VCL and the second node N2. A first electrode of the fifth transistor T5 may receive the compensation voltage VCOMP through the compensation voltage line VCL, and a second electrode of the fifth transistor T5 may be connected to the second node N2 to be connected (e.g., electrically connected) to the first electrode of the first transistor T1. A gate of the fifth transistor T5 may receive a compensation scan signal GC through the i-th second scan line GCLi. In case that the compensation scan signal GC is supplied to the compensation scan line GCLi, the fifth transistor T5 may be turned on to provide the compensation voltage VCOMP to the second node N2, and a threshold voltage of the first transistor T1 may be compensated during a compensation period.

The sixth transistor T6 may be connected between the first electrode of the first transistor T1 and the light emitting element LD. For example, a gate of the sixth transistor T6 may receive an emission signal EM through the i-th emission line ESLi (hereinafter an emission line). A first electrode of the sixth transistor T6 may be connected to the cathode of the light emitting element LD through a fourth node N4, and a second electrode of the sixth transistor T6 may be connected to the first electrode of the first transistor T1 through the second node N2. The sixth transistor T6 may be referred to as a first emission control transistor. In case that the emission signal EM is supplied to the emission line ESLi, the sixth transistor T6 may be turned on to connect (e.g., electrically connect) the light emitting element and the first transistor T1.

The seventh transistor T7 may be connected between the second power line VSL and the third node N3. A first electrode of the seventh transistor T7 may be connected to the second electrode of the first transistor T1 through the third node N3, and a second electrode of the seventh transistor T7 may receive the second power supply voltage VSS through the second power line VSL. A gate of the seventh transistor T7 may be connected (e.g., electrically connected) to the emission line ESLi. The seventh transistor T7 may be referred to as a second emission control transistor. In case that the emission signal EM is supplied to the emission line ESLi, the seventh transistor T7 may be turned on to connect (e.g., electrically connect) the second electrode of the first transistor T1 and the second power line VSL.

In an embodiment, the sixth transistor T6 and the seventh transistor T7 are shown as connected to the same emission line ESLi to be turned on by the same emission signal EM, but this is an example. The sixth transistor T6 and the seventh transistor T7 may be independently turned on by different signals. In another example, in the pixel driving part PDC, any one of the sixth transistor T6 and the seventh transistor T7 may be omitted.

The eighth transistor T8 may be connected between the second initialization voltage line VIL2 and the fourth node N4. For example, the eighth transistor T8 may include a gate connected to the i-th fourth scan line GBLi, a first electrode connected to the second initialization voltage line VIL2, and a second electrode connected to the fourth node N4. The eighth transistor T8 may be referred to as a second initialization transistor. The eighth transistor T8 may supply the second initialization voltage VINT2 to the fourth node N4 corresponding to the cathode of the light emitting element LD in response to the second initialization scan signal GB transferred through the second initialization scan line GBLi. The cathode of the light emitting element LD may be initialized by the second initialization voltage VINT2.

In an embodiment, some of the second to eight transistors T2, T3, T4, T5, T6, T7, T8 may be substantially simultaneously turned on by the same scan signal. For example, the eighth transistor T8 and the fifth transistor T5 may be substantially simultaneously turned on by the same scan signal. For example, the eighth transistor T8 and the fifth transistor T5 may be operated by the same compensation scan signal GC. The eighth transistor T8 and the fifth transistor T5 may be substantially simultaneously turned on/off by the same compensation scan signal GC. For example, the compensation scan line GCLi and the second initialization scan line GBLi may be provided as a substantially single scan line. Accordingly, initialization of the cathode of the light emitting element LD may be achieved together with the threshold voltage compensation of the first transistor T1 at the substantially same timing. However, this is an example, but embodiments are not limited thereto.

For example, applying the same power supply voltage may lead to the initialization of the cathode of the light emitting element LD and the threshold voltage compensation of the first transistor T1. For example, the compensation voltage line VCL and the second initialization voltage line VIL2 may be provided as a substantially single power supply voltage line. For example, a power supply voltage may lead to a cathode initialization operation and a compensation operation of the driving transistor, and thus designing the driving part may be simplified. However, this is an example, but embodiments are not limited thereto.

The first capacitor C1 may be disposed between the first node N1 and the third node N3. The first capacitor C1 may store charges corresponding to a voltage difference between the first node N1 and the third node N3. The first capacitor C1 may be referred to as a storage capacitor.

The second capacitor C2 may be disposed between the third node N3 and the second power line VSL. For example, an electrode of the second capacitor C2 may be connected to the second power line VSL to which the second power supply voltage VSS is supplied, and another electrode of the second capacitor C2 may be connected to the third node N3. The second capacitor C2 may store charges corresponding to a voltage difference between the second power supply voltage VSS and the second node N2. The second capacitor C2 may be referred to as a hold capacitor. The second capacitor C2 may have higher storage capacitance in comparison to the first capacitor C1. Accordingly, the second capacitor C2 may minimize a voltage difference in the third node N3 in response to a voltage difference at the first node N1.

In an embodiment, the light emitting element LD may be connected to the pixel driving part PDC through the fourth node N4. The light emitting element LD may include an anode connected to the first power line VDL and the cathode opposite thereto. In an embodiment, the light emitting element LD may be connected to the pixel driving part PDC through the cathode. For example, in the pixel PXij according to an embodiment, a connection node at which the light emitting element LD is connected to the pixel driving part PDC may be the fourth node, and the fourth node N4 may correspond to a connection node between the first electrode of the sixth transistor T6 and the cathode of the light emitting element LD. Accordingly, the potential of the fourth node N4 may substantially correspond to a cathode potential of the light emitting element LD.

For example, the anode of the light emitting element LD may be connected to the first power line VDL to receive the first power supply voltage VDD that is a constant voltage, and the cathode may be connected to the first transistor T1 through the sixth transistor T6. In an embodiment in which the first to eighth transistors T1 to T8 are N-type transistors, the potential of the third node N3, which corresponds to the source of the first transistor T1 being a driving transistor, may not be affected directly by the characteristics of the light emitting element LD. Accordingly, in case that the light emitting element LD is degraded, gate-source voltages Vgs of the transistors forming the pixel driving part PDC, e.g., the driving transistor, may be less affected. For example, the amount of change in a driving current due to the degradation of the light emitting element LD may be reduced, and thus afterimage defects of the display panel due to an increase in utilization time may be reduced and the lifetime may be enhanced.

In another example, as shown in FIG. 2B, the pixel PXij-1 may include a pixel driving part PDC-1 including two transistors T1 and T2, and one capacitor C1. The pixel driving part PDC-1 may be connected to the light emitting element LD, the write scan line GWLi, the data line DLj, the second power line VSL. The pixel driving part PDC-1 shown in FIG. 2B may correspond to one in which the third to eighth transistors T3 to T8 and the second capacitor C2 are omitted from the pixel driving part PDC shown in FIG. 2A.

Each of the first and second transistors T1 and T2 may be an N-type transistor or a P-type transistor. The embodiment describes an example case where each of the first and second transistors T1, T2 is the N-type transistor.

The first transistor T1 may include a gate connected to the first node N1, a first electrode connected to the second node N2, and a second electrode connected to the third node N3. The second node N2 may be connected to a first power line VDL through the light emitting element LD, and the third node N3 may be connected to a second power line VSL. The first transistor T1 may be connected to the light emitting element LD through the second node N2, and to the second power line VSL through the third node N3. The first transistor T1 may be a driving transistor.

The second transistor T2 may include a gate that receives the write scan signal GW through the write scan line GWLi, a first electrode connected to the data line DLj, and a second electrode connected to the first node N1. The second transistor T2 may supply the data signal DATA to the first node N1 in response to the write scan signal GW transferred through the write scan line GWRLi.

The first capacitor C1 may include an electrode connected to the first node N1 and an electrode connected to the third node N3. The capacitor C1 may store the data signal DATA transferred to the first node N1.

The light emitting element LD may include an anode and a cathode. In an embodiment, the anode of the light emitting element LD may be connected to the first power line VDL, and the cathode may be connected to the pixel driving part PDC-1 through the second node N2. In an embodiment, the cathode of the light emitting element LD may be connected to the first transistor T1. The light emitting element LD may emit light in response to the amount of a current flowing through the first transistor T1 of the pixel driving part PDC-1.

In an embodiment where the first and second transistors T1, T2 are the N-type transistors, the second node N2 at which the light emitting element LD is connected to the pixel driving part PDC-1 may correspond to a drain of the first transistor T1. For example, a change in a gate-source voltage (Vgs) of the first transistor T1 due to the light emitting element LD may be prevented. For example, the amount of change in the driving current due to the degradation of the light emitting element LD may be reduced, and thus afterimage defects of the display panel due to an increase in utilization time may be reduced and the lifetime may be enhanced.

FIGS. 2A and 2B show the pixel driving parts PDC and PDC-1 according to an embodiments, and in case that the pixel driving part is connected to the cathode of the light emitting element LD, the display panel according to an embodiment may be designed in various ways in terms of the number or the arrangement relationship of transistors, and the number or the arrangement relationship of the capacitors. Embodiments are not limited thereto.

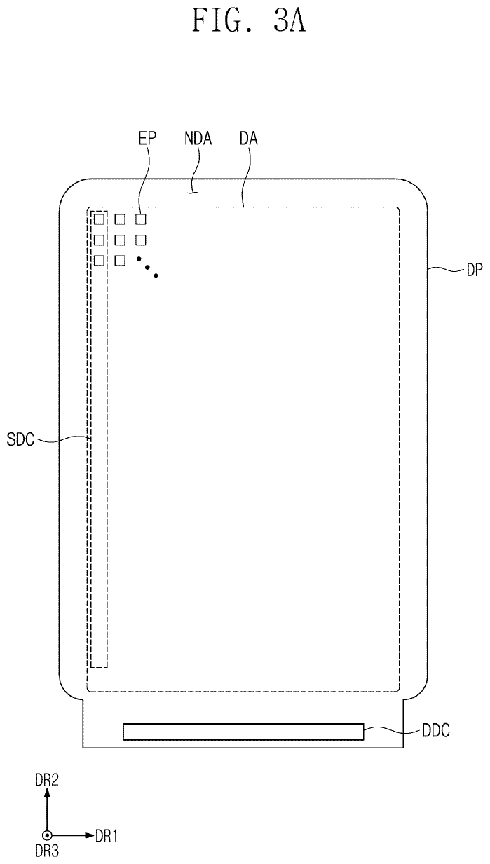

FIGS. 3A and 3B are schematic plan views of a display panel according to an embodiment. In each of FIGS. 3A and 3B, some components are omitted. Hereinafter, the embodiment will be described with reference to FIGS. 3A and 3B. Referring to FIG. 3A, a display panel DP in an embodiment may be divided into a display area DA and a peripheral area NDA (or a non-display area). The display area DA may include light emitting parts EP.

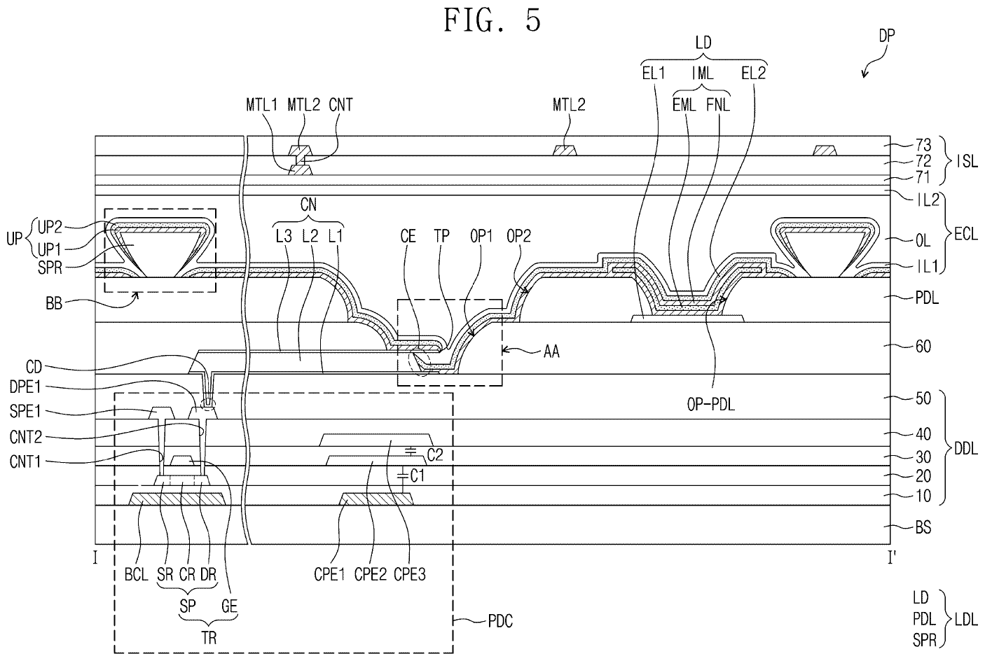

The light emitting parts EP may be areas in which the pixels PXij (see FIG. 1) emit light, respectively. For example, each of the light emitting parts EP may correspond to an emission opening OP-PDL (see FIG. 5) to be described below.

The non-display area NDA may be disposed adjacent to the display area DA. In an embodiment, the non-display area NDA may be shown to surround the edge portion of the display area DA. However, this is an example, and the non-display area NDA may be disposed in a side of the display area DA, or be omitted, but embodiments are not limited thereto.

In an embodiment, the scan driving part SDC and the data driving part DDC may be mounted in the display panel DP. In an embodiment, the scan driving part SDC may be disposed in the display area DA, and the data driving part DDC may be disposed in the non-display area NDA. The scan driving part SDC may overlap at least some of the light emitting parts EP disposed in the display area DA in a plan view. As the scan driving part SDC is disposed in the display area DA, the area of the non-display area NDA may be reduced in comparison to a typical display panel in which a scan driving part is disposed in the non-display area, and thus a display device may be readily implemented to have a thin bezel.

Unlike the shown in FIG. 3A, the scan driving part SDC may include two separate parts. The two scan driving parts SDC may be spaced apart in a horizontal direction with the center portion of the display area DA interposed between the two scan driving parts SDC. In another example, the scan driving part SDC may include two or more parts, but embodiments are not limited thereto.

FIG. 3A shows an example display panel, and the data driving part DDC may be disposed in the display area DA. For example, some of light emitting parts EP disposed in the display area DA may overlap the data driving part DDC in a plan view.

In an embodiment, the data driving part DDC may be provided in a driving chip type separately from the display panel DP to be connected to the display panel DP. However, this is an example, and the data driving part DDC and the scan driving part SDC may also be formed in the same processes so as to form the display panel DP, but embodiments are not limited thereto.

As shown in FIG. 3B, the display panel DP may have the shape in which the length corresponding to a first direction DR1 is longer than the length corresponding to a second direction DR2. In an embodiment, the display panel DP may include scan driving parts SDC1 and SDC2. The scan driving parts SDC1 and SDC2 may include a first scan driving part SDC1 and a second scan driving part SDC2 spaced apart from each other in the first direction DR1.

The first scan driving part SDC1 may be connected to some of the scan lines GL1 to GLn, and the second scan driving part SDC2 may be connected to the others of the scan lines GL1 to GLn. For example, the first scan driving part SDC1 may be connected to the odd scan lines GL1 to GLn, and the second scan driving part SDC2 may be connected to the even scan lines GL1 to GLn. FIG. 3B also illustrates pixels PX11 and PXnm and appropriate connections thereto.

FIG. 3B shows pads PD of the data lines DL1 to DLm for descriptive convenience. The pads PD may be formed at the end portions of the data lines DL1 to DLM. The data lines DL1 to DLm may be connected to the data driving part DDC (see FIG. 3A) through the pads PD.

According to an embodiment, some of the pads PD may be disposed in the non-display area at positions at which the pads are spaced apart from each other with the display area DA interposed between the pads. For example, some of the pads PD may be disposed in an upper side, e.g., a side adjacent to the first scan line GL1 among the scan lines GL1 to GLn, and the others may be disposed in a lower side, e.g., a side adjacent to the last scan line GLn of the scan lines GL1 to GLn. In an embodiment, the pads PD connected to the odd scan lines DL1 to DLm may be disposed in the upper side, and the pads PD connected to the even scan lines DL1 to DLm may be disposed in the lower side.

For example, the display panel DP may include upper side data driving parts connected to the pads PD disposed in the upper side and/or lower side data driving parts connected to the pads PD disposed in the lower side. However, this is an example, and the display panel DP may include an upper data driving part connected to the pads PD disposed in the upper side and/or one lower side data driving part connected to the pads PD disposed in the lower side. For example, the pads PD according to an embodiment may also be disposed in a side of the display panel DP to be connected to a single data driving part, but embodiments are not limited thereto.

For example, as described above with reference to FIG. 3A, the display panel DP in FIG. 3B may also include the scan driving part and/or the data driving part disposed in the display area DA, and accordingly, some of the light emitting parts disposed in the display area DA may overlap the scan driving part and/or the data driving part in a plan view.

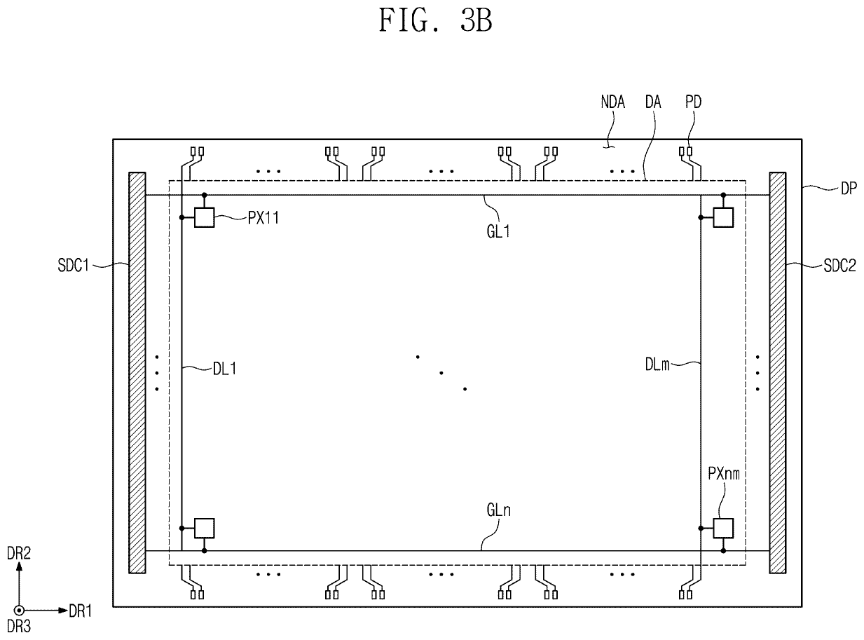

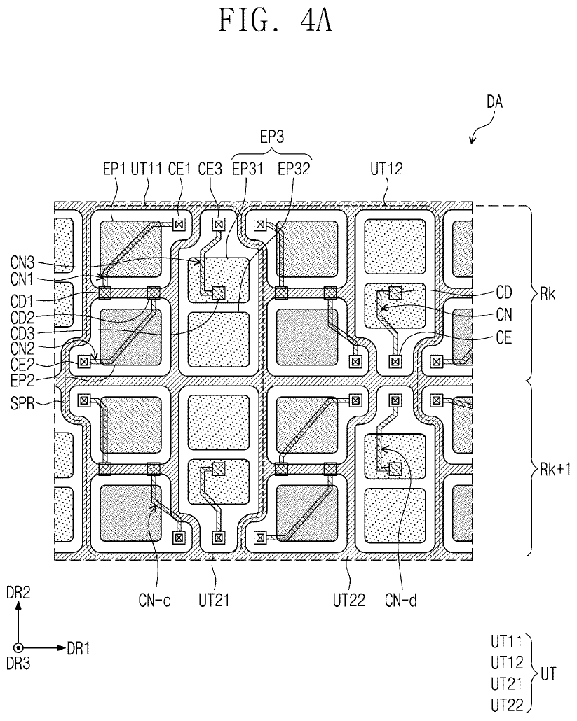

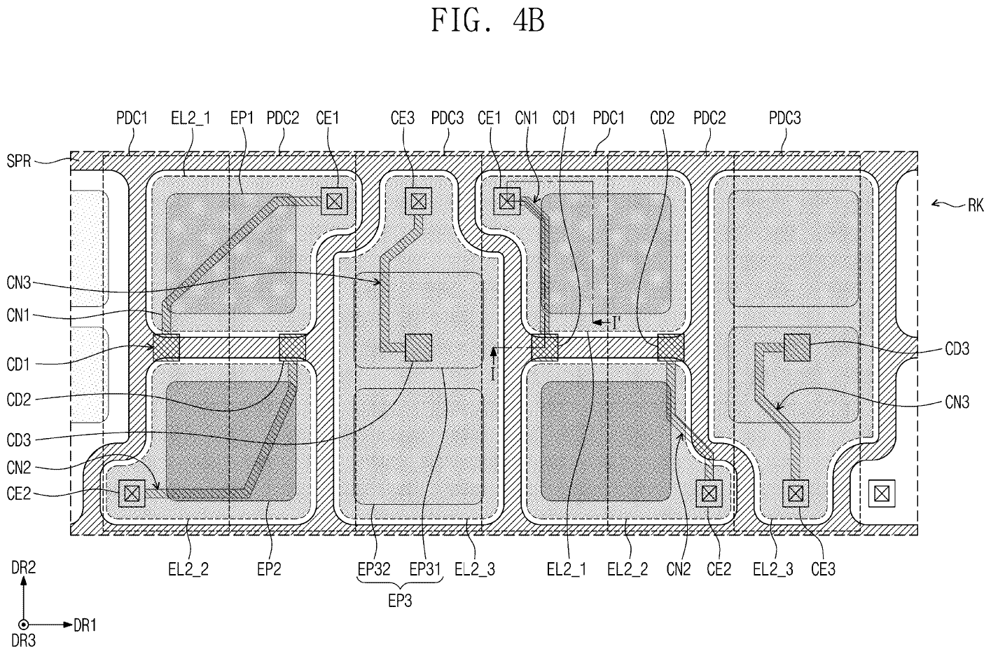

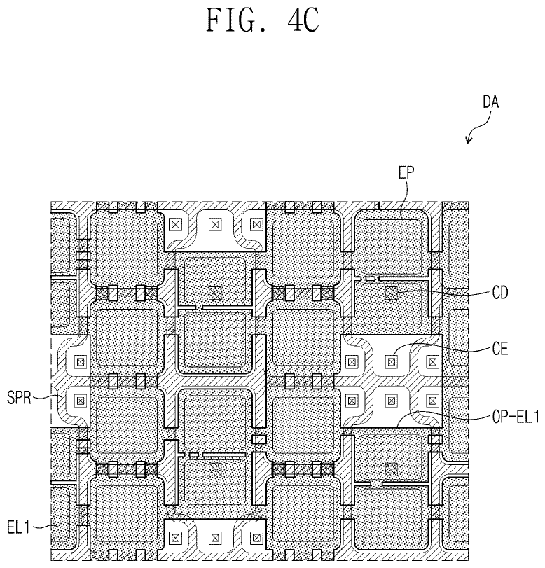

FIGS. 4A to 4C are enlarged schematic plan views of a partial area of a display panel according to an embodiment. FIG. 4A shows an area in which total four light emitting units UT are disposed in two rows and two columns, and FIG. 4B shows an enlarged schematic view of the partial area shown in FIG. 4A. FIG. 4C shows that some components in FIG. 4A are highlighted or some other components are omitted. Hereinafter, embodiments will be described with reference to FIGS. 4A to 4C.

In FIG. 4A, the light emitting units UT11, UT12, UT21, and UT22 in two rows and two columns are shown. The light emitting parts in the first row Rk may include the light emitting unit UT11 in the first row and first column and the light emitting unit UT12 in the first row and second column, and the light emitting parts in the second row Rk+1 may include the light emitting unit UT21 in the second row and first column and the light emitting unit UT22 in the second row and second column. FIG. 4B shows the light emitting parts in the first row Rk. FIG. 4A to FIG. 4C show, among the components of the display panel, a separator SPR, light emitting parts EP1, EP2, and EP3, connection lines CN1, CN2, and CN3, a first electrode EL1, and second electrodes EL2_1, EL2_2, and EL2_3 disposed in areas divided by the separator SPR.

As described above, the light emitting parts EP1, EP2, and EP3 may respectively correspond to the emission openings OP-PDL to be described below. For example, each of the light emitting parts EP1, EP2, and EP3 may be an area in which light is emitted by the foregoing light emitting element, and may correspond to a unit displaying an image displayed on the display panel DP. For example, the area may correspond to an area defined by the emission opening OP-PDL (see FIG. 5) to be described below, e.g., an area defined by the bottom surface (or lower surface) of the emission opening OP-PDL.

The light emitting parts EP1, EP2, and EP3 may include the first light emitting part EP1, the second light emitting part EP2, and the third light emitting part EP3. The first light emitting part EP1, the second light emitting part EP2, and the third light emitting part EP3 may display different color light. For example, the first light emitting part EP1 may display red light, the second light emitting part EP2 may display green light, and the third light emitting part EP3 may display blue light, but the combination of the colors is not limited thereto. For example, at least two of the light emitting parts EP1, EP2, EP3 may emit the same color light. For example, all the first to third light emitting parts EP1, EP2, EP3 may emit blue light or white light.

For example, the third light emitting part EP3 that displays the light emitted by the third light emitting element among the light emitting parts EP1, EP2, and EP3 may include two sub-light emitting parts EP31 and EP32 spaced apart from each other in the second direction DR2. However, this is an example, and the third light emitting part EP3 may have a pattern having an integrated shape like the other light emitting parts EP1 and EP2. In another example, at least one of the other light emitting parts EP1 and EP2 may also include sub-light emitting parts that are spaced apart from each other, but embodiments are not limited thereto.

In an embodiment, the light emitting parts in the first row Rk may be constituted of the light emitting parts in a type that the light emitting unit UT11 in the first row and first column and the light emitting unit UT12 in the first row and second column are repeatedly arranged. The light emitting parts in the second row Rk+1 may be constituted of light emitting parts in a type that the light emitting unit UT21 in the second row and first column and the light emitting unit UT22 in the second row and second column are repeatedly arranged. The shape and the arrangement of the third light emitting part forming the light emitting unit UT11 may be axisymmetric (or symmetric) with that of the third emitting part forming the light emitting unit UT21 with respect to the axis parallel to the first direction DR1. The shape and the arrangement of the third light emitting part forming the light emitting unit UT12 may be axisymmetric (or symmetric) with that of the third emitting part forming the light emitting unit UT22 with respect to the axis parallel to the first direction DR1.

Hereinafter, the light emitting unit UT11 in the first row and first column will be described. For descriptive convenience, FIG. 4B illustrates second electrodes EL2_1, EL2_2, and EL2_3, pixel driving parts PDC, and connection lines CN. The second electrodes EL2_1, EL2_2, and EL2_3 may be divided by the separator SPR and may be electrically cut. In an embodiment, a light emitting unit (e.g., a single light emitting unit) UT may include three light emitting parts EP1, EP2, and EP3. Accordingly, the light emitting unit UT may include the three second electrodes EL2_1, EL2_2, and EL2_3 (hereinafter, first to third cathodes), three pixel driving parts PDC1, PDC2, and PDC3, and three connection lines CN1, CN2, and CN3. However, this is an example, and the number and arrangement of the light emitting units UT may be designed in various ways, but embodiments are not limited thereto.

The first to third pixel driving parts PDC1, PDC2, and PDC3 may be respectively connected to the light emitting parts forming the first to third light emitting parts EP1, EP2, and EP3. In the description, “be connected” includes not only a case of contacting to be directly connected, but also a case of being electrically connected.

For example, as shown in FIG. 4B, areas in which the pixel driving parts PDC1, PDC2, and PDC3 are respectively defined may correspond to a unit in which transistors and capacitors may be repeatedly arranged, the transistors and capacitors forming a pixel driving part PDC (see FIG. 2A) for driving the light emitting element in a pixel.

The first to third pixel driving parts PDC1, PDC2 and PDC3 may be sequentially disposed along the first direction DR1. For example, the disposition positions of the first to third pixel driving parts PDC1, PDC2, and PDC3 may be designed independently from the positions and shapes of the first to third light emitting parts EP1, EP2, and EP3.

For example, the first to third pixel driving parts PDC1, PDC2, and PDC3 may be disposed in an area divided by the separator, e.g., at a position different from the position at which the first to third cathodes EL2_1, EL2_2, and EL2_3 are disposed, or may be designed to have the area of a shape different from those of the first to third cathodes EL2_1, EL2_2, and EL2_3. In another example, the first to third pixel driving parts PDC1, PDC2, and PDC3 may be disposed in an area that is divided and defined by the separator and in which the first to third pixel driving parts PDC1, PDC2, and PDC3 are respectively disposed to overlap the positions at which the first to third cathodes EL2_1, EL2_2, and EL2_3 are disposed. The area may be designed to have the shape having the area similar to that of, for example, the first to third cathodes EL2_1, EL2_2, and EL2_3.

In an embodiment, each of the first to third pixel driving parts PDC1, PDC2, and PDC3 is shown as a rectangular shape, and each of the first to third light emitting parts EP1, EP2, and EP3 is arranged to have the area smaller than and a type different from the first to third pixel driving parts. The first to third cathodes EL2_1, EL2_2, and EL2_3 are shown as respectively disposed at positions to overlap the first to third light emitting parts EP1, EP2, and EP3, and to have irregular shapes.

Accordingly, as shown in FIG. 4B, the first pixel driving part PDC1 may be also disposed at a position to partially overlap the first light emitting part EP1, the second light emitting part EP2, and another adjacent light emitting unit. The second pixel driving part PDC2 may be disposed at a position to overlap the first light emitting part EP1, the second light emitting part EP2, and the third light emitting part EP3. The third pixel driving part PDC3 may be disposed at a position to overlap the third light emitting part EP3. This is an example, and the positions of the first to third pixel driving parts PDC1, PDC2 and PDC3 may be independently designed from the light emitting parts EP1, EP2, and EP3 in various shapes and arrangement, but embodiments are not limited thereto.

The connection line CN may be provided in plurality and spaced apart from each other. The connection lines CN may connect (e.g., electrically connect) the pixel driving parts and the light emitting elements. For example, the connection line CN may correspond to the node (sec N4 in FIG. 2A and N2 in FIG. 2B) at which the light emitting element LD is connected to the pixel driving part PDC.

The connection line CN may include a first connection part (or an emission connection part CE) and a second connection part (or a driving connection part CD). The emission connection part CE may be provided to an end portion of the connection line CN and the driving connection part CD may be provided to another end portion of the connection line CN.

The driving connection part CD may be a part connected to the pixel driving part PDC in the connection line CN. In an embodiment, the driving connection part CD may be connected to an electrode of the transistor forming the pixel driving part PDC. For example, the driving connection part CD may be connected to the drain of the sixth transistor T6 shown in FIG. 2A or the drain of the first transistor T1 shown in FIG. 2B. Accordingly, the position of the driving connection part CD may correspond to the position of the transistor (see TR in FIG. 5) connected (e.g., physically connected) to the connection line CN in the pixel driving part. The emission connection part CE in the connection line CN may be a part connected to the light emitting element. In an embodiment, the emission connection part CE may be connected to the second electrode EL2 (hereinafter, the cathode) of the light emitting element.

The light emitting unit UT may include first to third connection lines CN1, CN2, and CN3. The first connection line CN1 may connect the light emitting element forming the first light emitting part EP1 to the first pixel driving part PDC1, the second connection line CN2 may connect the light emitting element forming the second light emitting part EP2 to the second pixel driving part PDC2, and the third connection line CN3 may connect the light emitting element forming the third light emitting part EP3 to the third pixel driving part PDC3.

For example, the first third connection lines CN1, CN2, and CN3 may respectively connect the first to third cathodes EL2_1, EL2_2, and EL2_3 to the first to third pixel driving parts PDC1, PDC2, and PDC3. The first connection line CN1 may include a first driving connection part CD1 connected to the first pixel driving part PDC1, and the first emission connection part CE1 connected to the first cathode EL2_1. The second connection line CN2 may include a second driving connection part CD2 connected to the second pixel driving part PDC2, and a second emission connection part CE2 connected to the second cathode EL2_2. The third connection line CN3 may include a third driving connection part CD3 connected to the third pixel driving part PDC3, and a third emission connection part CE3 connected to the third cathode EL2_3.

The first to third driving connection parts CD1, CD2 and CD3 may be arranged along the first direction DR1. As described above, the first to third driving connection parts CD1, CD2, and CD3 may respectively correspond to the positions of connection transistors forming the first to third pixel driving parts PDC1, PDC2, and PDC3. In a pixel, the connection transistor may include, as an electrode (e.g., a single electrode), a connection node at which the pixel driving part is connected to the light emitting element, and, for example, may correspond to the sixth transistor T6 in FIG. 2A or the first transistor T1 in FIG. 2B. For example, the shape, positions, and arrangement of pixel driving parts of all the pixels may be simply formed and designed regardless of the shape, the size, or the emission color of the light emitting part.

In an embodiment, the first to third emission connection parts CE1, CE2, and CE3 may be disposed at a non-overlap position with the light emitting parts EP1, EP2, and EP3 in a plan view. As will be described below, the emission connection part CE (see FIG. 5) of the connection line CN may be a part connected to the light emitting element LD (see FIG. 5), and also a part in which a tip part TP (see FIG. 5) is defined, and thus the emission connection part CE may be provided at a non-overlap position with the emission opening OP-PDL. For example, the emission connection parts CE1, CE2, and CE3 may be disposed in the respective cathodes EL2_1, EL2_2, and EL2_3 at positions spaced apart from the light emitting parts EP1, EP2, and EP3, and the cathodes EL2_1, EL2_2, and EL2_3 may include some areas protruding from the light emitting parts EP1, EP2, and EP3 in a plan view in order to connect with the connection lines CN1, CN2, CN3 at the positions at which the emission connection parts CE1, CE2, and CE3 are disposed.

For example, the first cathode EL2_1 may include a protrusion part having the shape protruding from the first light emitting part EP1 at the non-overlap position with the first light emitting part EP1 in order to be connected to the first connection line CN1, and the emission connection part CE1 may be provided in the protrusion part.

For example, the first pixel driving part PDC1, e.g., the first driving connection part CD1 at a position at which the first connection line CN1 is connected to the transistor TR may be formed at a non-overlap position with the first light emitting part EP1 in a plan view. According to an embodiment, the first connection line CN1 may be disposed in the light emitting part EP1, and thus the first cathode EL2_1 and the first pixel driving part PDC1 spaced apart from each other may be readily connected.

For example, the third pixel driving part PDC3, e.g., the third driving connection part CD3 at the position at which the third connection line CN3 is connected to the transistor TR may be formed at a non-overlap position with the third emission connection part CE3, and may be disposed at an overlap position with the third light emitting part EP3. According to an embodiment, the third cathode EL2_3 may be connected to the third pixel driving part PDC3 through the third connection line CN3, and thus, in designing the third pixel driving part PDC3, restrictions according to the position or the shape of the third light emitting part EP3 are reduced to enhance the degree of freedom of design.

Referring to FIG. 4A again, the shape and the arrangement of the first and second light emitting parts forming the light emitting unit UT11 may be axisymmetric (or symmetric) with that of the first and second light emitting parts forming the light emitting unit UT12 with respect to the axis parallel to the second direction DR2. The shape of the third light emitting part forming the light emitting unit UT11 may be axisymmetric (or symmetric) with that of the third emitting part forming the light emitting unit UT12 with respect to the axis parallel to the first direction DR1 (or, symmetrical vertically based on the second direction DR2). For example, due to the features of the shapes and arrangement of the first row light emitting units UT11 and UT12, the second row light emitting units TU21 and UT22 may be constituted of light emitting parts in which the first row light emitting units UT11 and UT12 are shifted in the first direction DR1. For example, the light emitting unit UT21 in the second row and first column may be constituted of the light emitting parts having the same shape as the light emitting unit UT12 in the first row and second column, and the light emitting unit UT22 in the second row and second column may be constituted of light emitting parts having the same shape as the light emitting unit UT11 in the first row and first column.

Accordingly, the shapes and arrangement types of the connection lines CN-c disposed in the light emitting unit UT21 in the second row and the first column may be the same as the connection lines CN1, CN2, and CN3 disposed in the light emitting unit UT12 in the first row and second column. For example, the shapes and arrangement types of the connection lines CN-d disposed at the light emitting unit UT22 in the second row second column may be the same as the connection lines CN1, CN2, and CN3 disposed at the light emitting unit UT11 in the first row and first column.

Referring to FIG. 4C, the first electrode EL1 (hereinafter, the anode) according to an embodiment may be commonly provided to the light emitting parts EP1, EP2, and EP3. For example, the anode EL1 may be provided as a layer (e.g., a single layer) that is entirely integrated with (or entirely cover) the display area DA, and thus, the anode layer may be disposed to overlap the separator SPR. In another example, the anodes EL1 of the respective light emitting elements may be provided in independently conductive pattern layers spaced apart from each other, or may be connected (e.g., electrically connected) through another conductive layer. Accordingly, the anode EL1 may be disposed not to overlap the separator SPR.

As described above, the first power supply voltage VDD is applied to the anode EL1 and a common voltage may be provided to all the light emitting parts. The anode EL1 may be connected to the first power line VDL (see FIG. 2A), which provides the first power supply voltage VDD in the non-display area NDA, or be also connected to the first power line VDL in the display area DA, but embodiments are not limited thereto.

For example, openings OP-EL1 may be formed in the anode EL1 according to an embodiment, and the openings OP-EL1 may penetrate through the anode EL1 layer. The openings OP-EL1 of the layer of the anode EL1 may be disposed at a non-overlap position with the light emitting parts EP, and may be formed at an overlap position with the separator SPR. The openings OP-EL1 may function discharge of a gas generated from an organic layer disposed under the anode EL1, for example, a sixth insulation layer 60 (see FIG. 5) to be described below. Accordingly, the gas from the organic layer disposed under the light emitting element may be sufficiently discharged in the process of manufacturing the display panel, and, after manufacturing, the gas discharged from the organic layer may be reduced to decrease the rate of degradation of the light emitting element.

For example, by including connection lines between the light emitting element and the pixel driving part, in case that only the shape of the cathode is changed without changing the shape or arrangement of the light emitting parts, the light emitting elements may be readily connected to the pixel driving parts. Accordingly, the degree of design freedom for the disposition of the pixel driving parts, and the area or the resolution of the light emitting parts of the display panel may be readily increased.

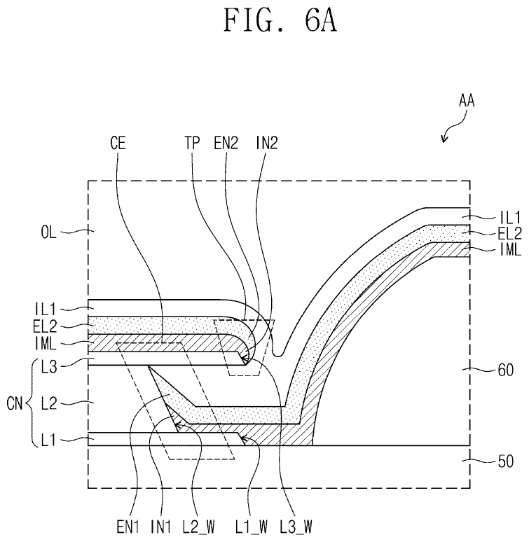

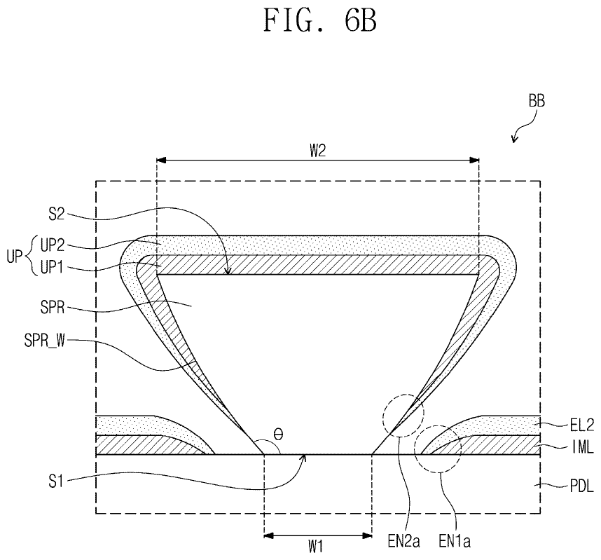

FIG. 5 is a schematic cross-sectional view of a display panel according to an embodiment. FIG. 6A is an enlarged schematic cross-sectional view of a portion of a display panel according to an embodiment. FIG. 6B is an enlarged schematic cross-sectional view of a portion of a display panel according to an embodiment. FIG. 5 is a schematic cross-sectional view showing a portion corresponding to line I-I′ of FIG. 4B. FIG. 6A shows an enlarged schematic cross-sectional view of area AA in FIG. 5, and FIG. 6B shows an enlarged schematic cross-sectional view of area BB in FIG. 5. Hereinafter, embodiments will be described with reference to FIGS. 5 to 6B.

Referring to FIG. 5, the display panel DP of an embodiment may include a base layer BS, a driving element layer DDL, a light emitting element layer LDL, an encapsulation layer ECL, and a sensing layer ISL. The driving element layer DDL may include insulation layers 10, 20, 30, 40, and 50 disposed on the base layer BS, and conductive pattern layers and semiconductor pattern layers disposed between the insulation layers. The conductive pattern layers and semiconductor pattern layers may be disposed between the insulation layers to form the pixel driving parts PDC. For descriptive convenience, FIG. 5 shows a cross section of any one portion in an area in which one light emitting part is disposed.

The base layer BS may be a member that provides a base surface on which the pixel driving parts PDC are disposed. The base layer BS may be a rigid substrate, or a flexible substrate that is bendable, foldable, rollable or the like. The base layer BS may be a glass substrate, a metal substrate, a polymer substrate or the like. However, embodiments are not limited thereto, and the base layer BS may be an inorganic layer, an organic layer, or a composite material layer.

The base layer BS may have a multilayer structure. The base layer BS may include a first polymer resin layer, a silicon oxide (SiOₓ) layer disposed on the first polymer resin layer, an amorphous silicon (a-Si) layer disposed on the silicon oxide layer, and a second polymer resin layer disposed on the amorphous silicon layer. The silicon oxide layer and the amorphous silicon layer may be referred to as a base barrier layer.

Each one of the first polymer resin layer and the second polymer resin layer may include a polyimide-based resin. For example, each one of the first polymer resin layer and the second polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. Further, in the description, “˜˜-based” resin means including a functional group of “˜˜”.

The insulation layers, the conductive layers, or the semiconductor layers disposed on the base layer BS each may be provided in a manner such as a coating process, a deposition process or the like. Then, through a plurality of photolithography processes, the insulation layers, the semiconductor layers, and the conductive layers may be selectively patterned to provide holes in the insulation layers, or provide the semiconductor pattern layers, the conductive pattern layers, the signal lines or the like.

The driving element layer DDL may include the first to sixth insulation layers 10, 20, 30, 40, 50, and 60, and the pixel driving parts PDC may be sequentially laminated on the base layer BS. In FIG. 5, one transistor TR and two capacitors C1 and C2 in the pixel driving part PDC are shown. The transistor TR may correspond to a transistor connected to the light emitting element LD through the connection line CN, e.g., a connection transistor connected to a node (e.g., the fourth node N4 in FIG. 2A or the second node N2 in FIG. 2B) corresponding to the cathode of the light emitting element LD, e.g., to the sixth transistor T6 in FIG. 2A or the first transistor T1 in FIG. 2B. For example, other transistors forming the pixel driving part PDC may have the same structure as the transistor TR (hereinafter, connection transistor) shown in FIG. 5. However, this is an example, and the other transistors forming the pixel driving part PDC may also have different structures from the connection transistor TR, but embodiments are not limited thereto.

The first insulation layer 10 may be disposed on the base layer BS. The first insulation layer 10 may include an inorganic material and/or organic material, and have a single layer structure or a multilayer structure. The first insulation layer 10 may include at least one of aluminum oxides, titanium oxide, silicon oxide, silicon oxynitride, zirconium oxide, and hafnium oxide. In an embodiment, the first insulation layer 10 is shown as a single silicon oxide layer. The insulation layers to be described below may include an inorganic layer and/or organic layer, and have a single layer structure or a multilayer structure. The inorganic material layer may include at least one of the aforementioned materials, but embodiments are not limited thereto.

The first insulation layer 10 may cover a bottom conductive layer BCL. For example, the display panel may further include the bottom conductive layer BCL overlapping the connection transistor TR. The bottom conductive layer BCL may block an electric potential caused by polarization of the base layer BS from affecting the connection transistor TR. For example, the bottom conductive layer BCL may block light incident from the bottom of the display panel DP to the connection transistor TR. At least one of an inorganic barrier layer and a buffer layer may be further disposed between the bottom conductive layer BCL and the base layer BS.

The bottom conductive layer BCL may include a reflective metal. For example, the bottom conductive layer BCL may include titanium (Ti), molybdenum (Mo), an alloy containing molybdenum, aluminum (Al), an alloy containing aluminum, an aluminum nitride (AIN), tungsten (W), a tungsten nitride (WN), copper (Cu) or the like.

In an embodiment, the bottom conductive layer BCL may be connected to the source of the connection transistor TR through a source pattern electrode SPE1. For example, the bottom conductive layer BCL may be synchronized with the source of the connection transistor TR. However, this is an example, and the bottom conductive layer BCL may be connected to the gate of the connection transistor TR to be synchronized with the gate. In another example, the bottom conductive layer BCL may be connected to another electrode to be independently applied with an electrostatic voltage or a pulse signal. In another example, the bottom conductive layer BCL may be provided in an isolated type from another conductive pattern layer. The bottom conductive layer BCL according to an embodiment may be provided in various types, but embodiments are not limited thereto.

The connection transistor TR may be disposed on the first insulation layer 10. The connection transistor TR may include a semiconductor pattern layer SP and a gate electrode GE. The semiconductor pattern layer SP may be disposed on the first insulation layer 10. The semiconductor pattern layer SP may include an oxide semiconductor. For example, the oxide semiconductor may include a transparent conductive oxide (TCO) such as indium tin oxide (ITO), indium zinc oxide (IZO), indium gallium zinc oxide (IGZO), zinc oxide (ZnO) or indium oxide In₂O₃ or the like. However, embodiments are not limited thereto, and the semiconductor pattern layer may also include amorphous silicon, low-temperature polycrystalline silicon, or polycrystalline silicon.

The semiconductor pattern layer SP may include a source region SR, a drain region DR, and a channel region CR divided according to the degree of the conductivity. The channel region CR may be a part overlapping the gate electrode GE in a plan view. The source region SR and the drain region DR may be spaced apart from each other with the channel region CR interposed between the source region SR and the drain region DR. In case that the semiconductor pattern layer SP is an oxide semiconductor, each of the source region SR and the drain region DR may be a reduced region. Accordingly, each of the source region SR and the drain region DR may include a relatively higher reduced metal content in comparison to the channel region CR. In another example, in case that the semiconductor pattern layer SP is polycrystalline silicon, each of the source region SR and the drain region DR may be a region doped with dopants at a high concentration.

The source region SR and the drain region DR may have a relatively higher conductivity than the channel region CR. The source region SR may correspond to a source electrode of the connection transistor TR, and the drain region DR may correspond to the drain electrode of the connection transistor TR. As shown in FIG. 5, separate source pattern electrode SPE1 and drain pattern electrode DPE1 respectively connected to the source region SR and the drain region DR may be further included. For example, the separate source pattern electrode SPE1 and drain pattern electrode DPE1 may be integral with one of lines forming the pixel driving parts (see FIGS. 2A and 2B), but embodiments are not limited thereto.

The second insulation layer 20 may commonly overlap pixels and cover the semiconductor pattern layer SP. The second insulation layer 20 may include an inorganic layer and/or organic layer, and have a single layer structure or a multilayer structure. The second insulation layer 20 may include at least one of aluminum oxide, titanium oxide, silicon oxide, silicon nitride, silicon oxynitride, zirconium oxide, and hafnium oxide. In an embodiment, the second insulation layer 20 may be a single silicon oxide layer.

The gate electrode GE may be disposed on the second insulation layer 20. The gate electrode GE may correspond to the gate of the connection transistor TR. For example, the gate electrode GE may be disposed on an upper side of the semiconductor pattern layer SP. However, this is an example, and the gate electrode GE may be disposed on the lower side of the semiconductor pattern layer SP, but embodiments are not limited thereto.

The gate electrode GE may include titanium (Ti), silver (Ag), molybdenum (Mo), aluminum (Al), aluminum nitride (AlN), tungsten (W), tungsten nitride (WN), copper (Cu), an alloy thereof or the like, but embodiments are not limited thereto.

The third insulation layer 30 may be arranged on the gate electrode GE. The third insulation layer 30 may include an inorganic layer and/or organic layer, and have a single layer structure or a multilayer structure. The third insulation layer 30 may include at least one of aluminum oxide, titanium oxide, silicon oxide, silicon nitride, silicon oxynitride, zirconium oxide, and hafnium oxide.

A first capacitor electrode CPE1 and a second capacitor electrode CPE2 among the conductive pattern layers SPE1, DPE1, CPE1, CPE2, and CPE3 may form the first capacitor C1. The first capacitor electrode CPE1 and the second capacitor electrode CPE2 may be spaced apart from each other with the first insulation layer 10 and the second insulation layer 20 interposed between the first capacitor electrode CPE1 and the second capacitor electrode CPE2.

In an embodiment, the first capacitor electrode CPE1 and the bottom conductive layer BCL may have an integral shape. For example, the second capacitor electrode CPE2 and the gate electrode GE may have an integral shape.

A third capacitor electrode CPE3 may be disposed on the third insulation layer 30. The third capacitor electrode CPE3 may be spaced apart from the second capacitor electrode CPE2 with the third insulation layer 30 interposed between the second capacitor electrode CPE2 and the third capacitor electrode CPE3. The third capacitor electrode CPE3 and the second capacitor electrode CPE2 may form the second capacitor C2.

The fourth insulation layer 40 may be disposed on the third insulation layer 30 and/or the third capacitor electrode CPE3. The fourth insulation layer 40 may be an inorganic material and/or organic material, and have a single layer structure or a multilayer structure. The fourth insulation layer 40 may include at least one of aluminum oxide, titanium oxide, silicon oxide, silicon nitride, silicon oxynitride, zirconium oxide, and hafnium oxide.

A source pattern electrode SPE1 and a drain pattern electrode DPE1 may be disposed on the fourth insulation layer 40. The source pattern electrode SPE1 may be connected to the source region SR of the connection transistor TR through a first contact hole CNT1, and the source pattern electrode SPE1 and the source region SR of the semiconductor pattern layer SP may function as the source of the connection transistor TR. The drain pattern electrode DPE1 may be connected to the drain region DR of the connection transistor TR through a second contact hole CNT2, and the drain pattern electrode DPE1 and the drain region DR of the semiconductor pattern layer SP may function as the drain of the connection transistor TR. The fifth insulation layer 50 may be disposed on the source pattern electrode SPE1 and the drain pattern electrode DPE1.

The connection line CN may be disposed on the fifth insulation layer 50. The connection line CN may connect (e.g., electrically connect) the pixel driving part PDC and the light emitting element LD. For example, the connection line CN may connect (e.g., electrically connect) the connection transistor TR and the light emitting element LD. The connection line CN may be a connection node which electrically connects the pixel driving part PDC and the light emitting element LD. For example, the connection line CN may correspond to the fourth node N4 in FIG. 2A, or to the second node N2 in FIG. 2B. This is an example. In case that the connection line CN may be connected to the light emitting element LD, the connection line CN may be defined as a connection node with various elements among the elements forming the pixel driving part PDC according to the design of the pixel driving part PDC, but embodiments are not limited thereto.

The sixth insulation layer 60 may be disposed on the connection line CN. The sixth insulation layer 60 may be disposed on the fifth insulation layer 50 to cover the connection line CN. Each of the fifth insulation layer 50 and the sixth insulation layer 60 may be an organic layer. For example, each of the fifth and sixth insulation layers 50 and 60 may include a general purpose polymer such as benzocyclobutene (BCB), polyimide, hexamethyldisiloxane (HMDSO), polymethylmethacrylate (PMMA), or polystyren (PS), a polymer derivative having a phenol-based group, an acryl-based polymer, an imide-based polymer, an allyl ether-based polymer, an amide-based polymer, a fluorine-based polymer, a p-xylene-based polymer, a vinylalcohol-based polymer, or a blend thereof.

An opening exposing at least a portion of the connection line CN may be provided in the sixth insulation layer 60. The connection line CN may be connected (e.g., electrically connected) to the light emitting element LD through the portion exposed from the sixth insulation layer 60. For example, the connection line CN may connect (e.g., electrically connect) the connection transistor TR and the light emitting element LD. A detailed description thereabout will be provided below. In the display panel DP according to an embodiment, the sixth insulation layer 60 may be omitted or provided in plurality, but embodiments are not limited thereto.

The light emitting element layer LDL may be disposed on the sixth insulation layer 60. The light emitting element layer LDL may include a pixel definition layer PDL, the light emitting element, and the separator SPR. The pixel definition layer PDL may be an organic layer. For example, the pixel definition layer PDL may include a general purpose polymer such as benzocyclobutene(BCB), polyimide, hexamethyldisiloxane (HMDSO), polymethylmethacrylate (PMMA), or polystyrene (PS), a polymer derivative having a phenol-based group, an acryl-based polymer, an imide-based polymer, an allyl ether-based polymer, an amide-based polymer, a fluorine-based polymer, a p-xylene-based polymer, a vinylalcohol-based polymer, or a blend thereof.

In an embodiment, the pixel definition layer PDL may have light absorption property, and, for example, may have a black color. For example, the pixel definition layer PDL may include a black coloring agent. The black coloring agent may include a black dye or a black pigment. The black coloring agent may include carbon black, a metal such as chromium, or an oxide thereof. The pixel definition layer PDL may correspond to a light blocking pattern layer having light blocking characteristics.

An opening OP-PDL (hereinafter, an emission opening) exposing at least a portion of the first electrode EL1 may be formed in the pixel definition layer PDL. The emission opening OP-PDL may be provided in plurality to be disposed in correspondence to the light emitting elements, respectively. The emission opening OP-PDL may be an area in which all the components of the light emitting element LD overlap, and light emitted from the light emitting element LD is substantially displayed. Accordingly, the shape of the foregoing light emitting part EP (sec FIGS. 3A and 4C) may substantially correspond to the shape of the emission opening OP-PDL in a plan view.

The light emitting element LD may include a first electrode EL1, an intermediate layer IML, and a second electrode EL2. The first electrode EL1 may be a semi-permeable, permeable, or reflective electrode. According to an embodiment, the first electrode EL1 may include a reflective layer composed of silver (Ag), magnesium (Mg), aluminum (Al), platinum (Pt), palladium (Pd), gold (Au), Nickel (Ni), neodymium (Nd), Iridium (Ir), Chromium (Cr), or a compound thereof, etc., and a transparent or semi-transparent electrode layer provided on the reflective layer. The transparent or semi-transparent electrode layer may include at least one selected from a group consisting of indium tin oxide (ITO), indium zinc oxide (IZO), indium gallium zinc oxide (IGZO), zinc oxide (ZnO) or indium oxide (In₂O₃), and aluminum-doped zinc oxide (AZO). For example, the first electrode EL1 may include a laminate structure of ITO/Ag/ITO.

In an embodiment, the first electrode EL1 may be the anode of the light emitting element LD. For example, the first electrode EL1 may be connected to the first power line VDL (see FIG. 2A), and may be applied with the first power supply voltage VDD (see FIG. 2A). The first electrode EL1 may be connected to the first power line VDL in the display area DA, or may be connected to the first power line VDL in the non-display area NDA. In the latter case, the first power line VDL may be disposed in the non-display area NDA, and the first electrode EL1 may have the shape extending to the non-display area NDA.

In the cross-sectional view in FIG. 5, the first electrode EL1 is shown to overlap the emission opening OP-PDL and not to overlap the separator SPR, but as shown in FIG. 4C, the first electrodes EL1 of the light emitting elements may have an integral shape, and the openings in a partial area may have a mesh or lattice shape. For example, in case that the first power supply voltage VDD may be equally applied to the first electrodes EL1 of the light emitting elements, the shape of each of the first electrode EL1 may be provided in various ways, but embodiments are not limited thereto.

The intermediate layer IML may be disposed between the first electrode EL1 and the second electrode EL2. The intermediate layer IML may include the light emitting layer EML and a function layer. The light emitting element LD may include the intermediate layer IML in various structures, but embodiments are not limited thereto. For example, the functional layer FNL may be provided in a plurality, and be formed as two or more layers spaced apart from each other with the light emitting layer EML interposed between two or more layers. In another example, the functional layer FNL in an embodiment may be omitted.

The light emitting layer EML may include an organic light emitting material. For example, the light emitting layer EML may include an inorganic light emitting material, or may be formed as a mixture layer of an organic light emitting material and an inorganic light emitting material. In an embodiment, the light emitting layer EML included in adjacent light emitting parts EP may include light emitting materials displaying different colors. For example, the light emitting layer EML included in each of the light emitting parts EP may provide light of any one color among blue, red, or green. However, embodiments are not limited thereto, and the light emitting layers EML respectively disposed in all the light emitting parts EP may have a light emitting material displaying the light of the same color. For example, the light emitting layers EML may provide blue light, or white light. For example, FIG. 5 shows an embodiment in which the light emitting layer EML and the functional layer FNL have different shapes. However, embodiments are not limited thereto, and the light emitting layer EML and the functional layer FNL may be disposed to have the same shape in a plan view.

The functional layer FNL may be disposed between the first electrode EL1 and the second electrode EL2. For example, the functional layer FNL may be disposed between the first electrode EL1 and the light emitting layer EML, or between the second electrode EL2 and the light emitting layer EML. In another example, the functional layer FNL may be disposed between first electrode EL1 and the light emitting layer EML, and also between the second electrode EL2 and the light emitting layer EML. In an embodiment, the light emitting layer EML is shown as being inserted in the functional layer FNL. However, this is an example, and the functional layer FNL may include a layer disposed between the light emitting layer EML and the first electrode EL1, and/or a layer disposed between the light emitting layer EML and the second electrode EL2, or each of the layers may be provided in plurality. Embodiments are not limited thereto.

The functional layer FNL may control movement of charges between the first electrode and the second electrode. The functional layer FNL may include hole injection/transport materials, and/or electron injection/transport materials. The functional layer FNL may include at least one of an electron blocking layer, a hole transport layer, a hole injection layer, a hole blocking layer, an electron transport layer, an electron injection layer, and a charge generation layer.

The second electrode EL2 may be disposed on the intermediate layer IML. As described above, the second electrode EL2 may be connected to the connection line CN to be connected (e.g., electrically connected) to the pixel driving part PDC. For example, the second electrode EL2 may be connected (e.g., electrically connected) to the connection transistor TR through the connection line CN.

As described above, the connection line may include the driving connection part CD and the emission connection part CE. The driving connection part CD in the connection line CN may be connected to the pixel driving part PDC, and be substantially connected to the connection transistor TR. In an embodiment, the driving connection part CD may penetrate through the fifth insulation layer 50 to be connected (e.g., electrically connected) to the drain region DR of the semiconductor pattern layer SP through the drain pattern electrode DPE1. The emission connection part CE in the connection line CN may be connected to the light emitting element LD. The emission connection part CE may be a portion defined in an area exposed from the sixth insulation layer 60, and connected to the second electrode EL2. For example, the emission connection part CE may include the tip part TP.

The emission connection part CE of the connection line CN will be described with reference to FIGS. 5 and 6A. As shown in FIGS. 5 and 6A, the connection line CN may have a three-layer structure. For example, the connection line CN may include a first layer L1, a second layer L2, and a third layer L3 sequentially laminated along the third direction DR3. The second layer L2 may include a different material from the first layer L1. For example, the second layer L2 may have a different material from the third layer L3. The second layer L2 may have a thicker thickness than the first layer L1. For example, the second layer L2 may have a thicker thickness than the third layer L3. The second layer L2 may include a material having a high conductivity. In an embodiment, the second layer L2 may include aluminum (Al).

The first layer L1 may include a material having a lower etch rate than the second layer L2. For example, the first layer L1 and the second layer L2 may be materials having high etch selectivities. In an embodiment, the first layer L1 may include titanium (Ti), and the second layer L2 may include aluminum (Al). For example, a side surface L1_W of the first layer L1 may be formed outer than a side surface L2_W of the second layer L2. For example, the emission connection part CE of the connection line CN may have the shape that the side surface L1_W of the first layer L1 protrudes outside from the side surface L2_W of the second layer L2. For example, the emission connection part CE of the connection line CN may have the shape that the side surface L2_W of the second layer L2 is retracted (or recessed) from the side surface L1_W of the first layer L1.

For example, the third layer L3 may include a material having a lower etch rate than the second layer L2. For example, the third layer L3 and the second layer L2 may be materials having high etch selectivities. In an embodiment, the third layer L3 may include titanium (Ti), and the second layer L2 may include aluminum (Al). For example, the side surface L3_W of the third layer L3 may be formed outer than the side surface L2_W of the second layer L2. For example, the emission connection part CE of the connection line CN may have the shape that the side surface L3_W of the third layer L3 protrudes outside from the side surface L2_W of the second layer L2. For example, the emission connection part CE of the connection line CN may have an undercut shape or an overhang structure, and the tip part TP of the emission connection part CE may be defined by a portion of the third layer, the portion protruding higher in comparison to the second layer L2.

The sixth insulation layer 60 and the pixel definition layer PDL may expose at least a portion of the tip part TP and at least a portion of the side surface L2_W of the second layer L2. For example, a first opening OP1 exposing a side of the connection line CN may be formed in the sixth insulation layer 60, and a second opening OP2 overlapping the first opening OP1 may be formed in the pixel definition layer PDL. The area of the second opening OP2 may be larger than that of the first opening OP1. However, embodiments are not limited thereto. In case that at least a portion of the tip part TP and at least a portion of the side surface L2_W of the second layer L2 may be exposed, the area of the second opening OP2 may be smaller than or the same as the first opening OP1.

The intermediate layer IML may be disposed on the pixel definition layer PDL. The intermediate layer IML may also be disposed on at least a portion of the sixth insulation layer 60, the portion being exposed by the second opening OP2 of the pixel definition layer PDL. For example, the intermediate layer IML may also be disposed on at least a portion of the connection line CN, the portion being exposed by the first opening OP1 of the sixth insulation layer 60. As shown in FIG. 6A, the intermediate layer IML may include an end portion IN1 disposed along the top surface (or upper surface) of the sixth insulation layer 60, and another end portion IN2 disposed along the top surface (or upper surface) of the tip part TP. For example, when viewed in a cross-sectional view, the intermediate layer IML may have the shape having a partially disconnected shape based on the tip part TP in the area in which the emission connection part CE is defined. In a plan view, the intermediate layer IML may have an integral shape that is entirely connected in an area defined by a closed line by the separator (see FIG. 4).

The second electrode EL2 may be disposed on the intermediate layer IML. The second electrode EL2 may also be disposed on a portion of the sixth insulation layer 60, which is exposed by the second opening OP2 of the pixel definition layer PDL. For example, the second electrode EL2 may also be disposed on at least a portion of the connection line CN, the portion being exposed by the first opening OP1 of the sixth insulation layer 60. As shown in FIG. 6A, the second electrode EL2 may include an end portion EN1 of the second electrode EL2 disposed along the top surface (or upper surface) of the fifth insulation layer 50, and another end portion EN2 disposed along the top surface (or upper surface) of the tip part TP. For example, when viewed in a cross-sectional view, the second electrode EL2 may have the shape having a partially disconnected shape based on the tip part TP in the area in which the emission connection part CE is defined. In a plan view, the second electrode EL2 may have an integral shape that is entirely connected in an area defined by a closed line by the separator (see FIG. 4).

For example, the end portion EN1 of the second electrode EL2 may be disposed along a side surface of the second layer L2 to contact the side surface L2_W of the second layer L2. For example, through the difference in deposition angle between the second electrode EL2 and the intermediate layer IML, the second electrode EL2 may be provided to contact the exposed side surface L2_W of the second layer L2. For example, the second electrode EL2 may be connected to the connection line CN without a separate patterning process for the intermediate layer IML, and accordingly, the light emitting element may be connected (e.g., electrically connected) to the pixel driving part PDC through the connection line CN.

For example, in an embodiment, another end portion IN2 of the intermediate layer IML and another end portion EN2 of the second electrode EL2 are shown to cover the side surface L3_W of the third layer L3, but this is an example. At least a portion of the side surface L3_W of the third layer L3 may be exposed from another end portion IN2 of the intermediate layer IML and/or another end portion EN2 of the second electrode EL2.

As described above, the display panel DP may include the separator SPR. The separator SPR may be disposed on the pixel definition layer PDL. In an embodiment, the second electrode EL2 and the intermediate layer IML may be commonly deposited on the pixels through an open mask. For example, the second electrode EL2 and the intermediate layer IML may be divided by the separator SPR. As described above, the separator SPR may have a closed line shape for each of the light emitting parts, and thus the second electrode EL2 and the intermediate layer IML may have the shape divided for each of the light emitting parts. For example, the second electrode EL2 and the intermediate layer IML may be electrically independent for each adjacent pixel.

The separator SPR will be described with reference to FIGS. 5 and 6B. As shown in FIG. 6B, the separator SPR may have an inverse taper shape. For example, an angle (θ, hereinafter, a taper angle) of a side surface SPR_W of the separator SPR to the top surface (or upper surface) of the pixel definition layer PDL may be an obtuse angle. This is an example. In case that the separator SPR may electrically disconnect the second electrode EL2 for each pixel, the taper angle (θ) may be set in various ways. For example, the separator SPR may have the structure as the tip part TP, but embodiments are not limited thereto.

In an embodiment, the separator SPR may include a base resin and a scattering agent. The base resin may include at least one of a novolac-based resin and an epoxy-based resin. The scattering agent may include at least one of TiO₂, ZnO, Al₂O₃, SiO₂, and hollow silica. For example, the scattering agent may include TiO₂. The separator SPR may include about 1 wt % to about 11 wt % of the scattering agent, based on the total weight of the separator SPR. For example, the separator SPR may include about 8 wt % to about 10 wt % of the scattering agent, based on the total weight of the separator SPR. The function of the scattering agent will be described in the description of the manufacturing method of the display panel.

The separator SPR may have the insulation. Accordingly, the separator SPR may electrically disconnect the second electrode EL2 for each pixel.

The top of the separator SPR may be formed as a dummy layer UP. The dummy layer UP may include a first dummy layer UP1 disposed on the separator SPR and a second dummy layer UP2 disposed on the first dummy layer UP1. The first dummy layer UP1 and the intermediate layer IML may be formed in the same processes and may include the same material. The second dummy layer UP2 and the second electrode EL2 may be formed in the same processes and include the same material. For example, the first dummy layer UP1 and the second dummy layer UP2 may be concurrently provided in the manufacturing processes of the intermediate layer IML and the second electrode EL2. In another example, the display panel DP may not include the dummy layer UP.

As shown in FIG. 6B, in an embodiment, the second electrode EL2 may include a first end portion EN1a, and the second dummy layer UP2 may include a second end portion EN2a. The first end portion EN1a may be spaced apart from the separator SPR to be positioned on the pixel definition layer PDL, and the second end portion EN2a may be separated from the first end portion EN1a to be positioned on the side surface SPR_W of the separator SPR. In FIG. 6B, the first end portion EN1a is shown to be spaced apart by a certain interval (or distance) from the side surface SPR_W of the separator SPR, but embodiments are not limited thereto. In case that the first end portion EN1a is electrically disconnected, the first end portion EN1a may also contact the side surface SPR_W of the separator SPR. For example, in case that the first end portion EN1a and the second end portion EN2a are indiscriminately connected to each other, in case that a portion provided along the side surface SPR_W of the separator SPR is thin to make electric resistance large, the second electrode EL2 may be considered as divided by the separator SPR in a case where the second electrode EL2 is electrically disconnected between adjacent pixels.

In case that there is no separate patterning processes for the second electrode EL2 or the intermediate layer IML, it is possible to cause the second electrode EL2 or the intermediate layer IML to be divided for each pixel by providing thinly or preventing the second electrode EL2 or the intermediate layer IML from being provided the second electrode EL2 or the intermediate layer IML on the side surface SPR_W of the separator SPR. For example, in case that the second electrode EL2 and the intermediate layer IML may be electrically disconnected between adjacent pixels, the shape of the separator SPR may be modified in various ways, but embodiments are not limited thereto.

Referring to FIG. 5, the encapsulation layer ECL may be disposed on the light emitting element layer LDL. The encapsulation layer ECL may cover the light emitting element LD and the separator SPR. The encapsulation layer ECL may include a first inorganic layer IL1, an organic layer OL and a second inorganic layer IL2 that are sequentially laminated. However, embodiments are not limited thereto, and the encapsulation layer ECL may further include inorganic layers and organic layers. The encapsulation layer ECL may be a glass substrate.

The first and second inorganic layers IL1 and IL2 may protect the light emitting element LD from the moisture and oxygen outside the display panel DP, and the organic layer OL may protect the light emitting element LD from foreign matters such as particles remained in the processes of providing the first inorganic layer IL1. The first and second inorganic layers IL1 and IL2 may include a silicon nitride layer, a silicon oxynitride layer, a silicon oxide layer, a titanium oxide layer, an aluminum oxide layer or the like. The organic layer OL may include an acrylic-based organic layer, and the kind of the material is not limited thereto.

The sensing layer ISL may sense an external input. In an embodiment, the sensing layer ISL may be provided on the encapsulation layer ECL through consecutive processes. For example, the sensing layer ISL may be expressed as being disposed (e.g., directly disposed) on the encapsulation layer ECL. Being directly disposed may mean that another element is not disposed between the sensing layer ISL and the encapsulation layer ECL. For example, a separate adhesive member may not be disposed between the sensing layer ISL and the encapsulation layer ECL. This is an example. In the display panel DP according to an embodiment, the sensing layer ISL may be separately provided and then combined with the display panel DP through an adhesive member, but embodiments are not limited thereto.

The sensing layer ISL may include sensing conductive layers and sensing insulation layers. The sensing conductive layers may include a first sensing conductive layer MTL1 and a second sensing conductive layer MTL2, and the sensing insulation layers may include first to third sensing insulation layers 71, 72, and 73. However, this is an example, and the numbers of the sensing conductive layers and the sensing insulation layers are not limited to any one embodiment.

The first to third sensing insulation layers 71, 72, and 73 may respectively have single layer structures, or a multi-layer structure laminated along the third direction DR3. The first to third sensing insulation layers 71, 72, and 73 may include inorganic films. The inorganic film may include at least one of aluminum oxide, titanium oxide, silicon oxide, silicon nitride, silicon oxynitride, zirconium oxide, and hafnium oxide. The first to third sensing insulation layers 71, 72, and 73 may include organic films. The organic film may include at least one of an acrylic-based resin, a methacrylic-based resin, polyisoprene, a vinyl-based resin, an epoxy-based resin, an urethane-based resin, a cellulose-based resin, a siloxane-based resin, a polyimide based-resin, a polyamide-based resin, and a parylene-based resin.

The first sensing conductive layer MTL1 may be disposed between the first sensing insulation layer 71 and the second sensing insulation layer 72, and the second sensing conductive layer MTL2 may be disposed between the second sensing insulation layer 72 and the third sensing insulation layer 73. A portion of the second sensing conductive layer MTL2 may contact the first sensing conductive layer MTL1 through a contact hole CNT provided in the second sensing insulation layer 72. The first sensing conductive layer MTL1 and the second sensing conductive layer MTL2 may respectively have a single layer structure or a multilayer structure laminated along the third direction DR3.

The sensing conductive layer of the single layer structure may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), indium zinc tin oxide (IZTO) or the like. In another example, the transparent conductive layer may include a conductive polymer such as poly(3,4-ethylenedioxythiophene) (PEDOT), a metal nano-wire, graphene or the like.

The sensing conductive layer of the multilayer structure may include metal layers. For example, the metal layers may have a three-layer structure of titanium/aluminum/titanium. In another example, the sensing conductive layer of the multilayer structure may include at least one metal layer and at least one transparent conductive layer.

In the sensing layer ISL, the first sensing conductive layer MTL1 and the second sensing conductive layer MTL2 may form a sensor that senses an external input. The sensor may be driven in an electrostatic capacitance manner, e.g., driven in any one of a mutual-cap manner or a self-cap manner. This is an example. The sensor may also be driven in a resistance film manner, an ultrasonic manner, or an infrared manner besides the electrostatic capacitance manner, but embodiments are not limited thereto.

Each of the first sensing conductive layer MTL1 and the second sensing conductive layer MTL2 may include a transparent conductive oxide, or have a metal mesh shape provided from a non-transparent conductive material. In case that visibility of an image displayed on the display panel DP is not lowered, each of the first sensing conductive layer MTL1 and the second sensing conductive layer MTL2 may include various materials and various shapes, but embodiments are not limited thereto.

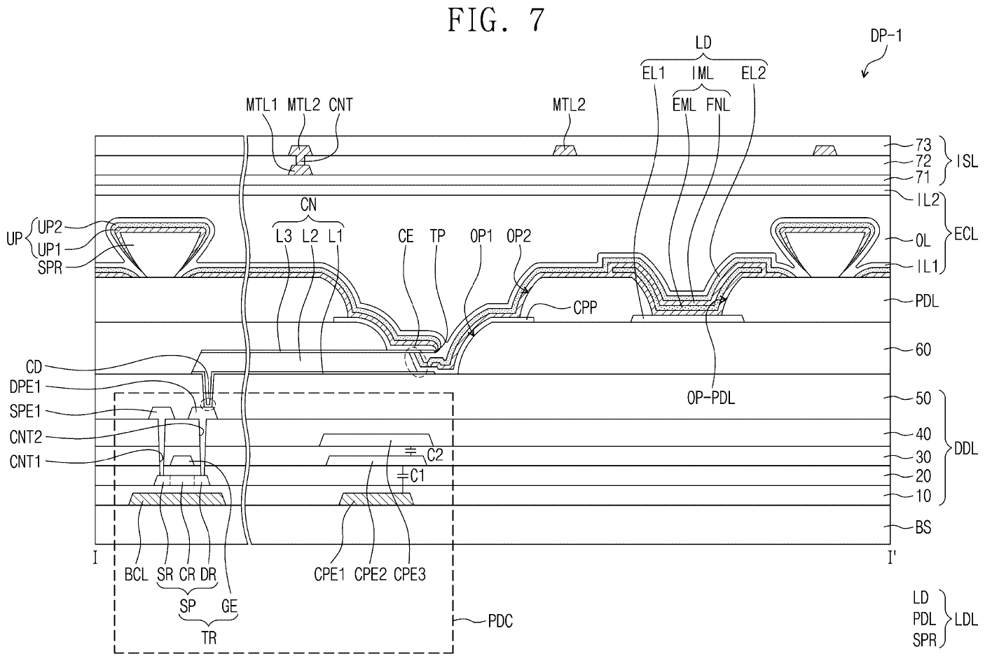

FIG. 7 is a schematic cross-sectional view of a display panel according to an embodiment. For convenience of description, FIG. 7 shows a cross-sectional view of an area corresponding to that in FIG. 5. Hereinafter, like numerals are given to like components described with reference to FIG. 1 to FIG. 6B, and redundant descriptions thereabout will be omitted for descriptive convenience.

The display panel DP-1 shown in FIG. 7 may further include a capping pattern layer CPP in comparison to that in FIG. 5. The capping pattern layer CPP may be disposed on the sixth insulation layer 60. For example, the capping pattern layer CPP may also be disposed on a portion of the connection line CN, the portion being exposed by the first opening OP1 of the sixth insulation layer 60. The capping pattern layer CPP may overlap the connection line CN, and may overlap the emission connection part CE and/or the tip part TP.

For example, when viewed in a cross-sectional view as shown in FIG. 7, the capping pattern layer CPP may have a partially disconnected shape based on the tip part TP in an area in which the emission connection part CE is defined. However, when viewed in a plan view, the capping pattern layer CPP may have an integral shape that is entirely connected in an area defined by the closed line by the separator (see FIG. 4). An end portion of the partially disconnected capping pattern layer CPP may contact a side of the second layer L2 of the connection line CN, and another end portion of the partially disconnected capping pattern layer CPP may be disposed on the third layer L3 of the connection line CN to cover the tip part TP.

The capping pattern layer CPP may include a conductive material. Accordingly, the second electrode EL2 may be connected (e.g., electrically connected) to the connection line CN through the capping pattern layer CPP. For example, the capping pattern layer CP may contact the side of the second layer L2 of the connection line, and then the second electrode EL2 may contact the capping pattern layer CPP to be entirely connected (e.g., electrically connected). The capping pattern layer CPP may be disposed relatively outer than the second layer L2, the second electrode EL2 may be connected (e.g., electrically connected) by contacting the second layer L2, and thus the connection line CN and the second electrode T2 may be more readily connected.

For example, the capping pattern layer CPP may include a material having a relatively low reactivity than the second layer L2 of the connection line CN. For example, the capping pattern layer CPP may include copper (Cu), silver (Ag), a transparent conductive oxide or the like. As the second layer L2 of the connection line CN is protected by the capping pattern layer CPP having the relatively low reactivity, materials included in the second layer L2 may be prevented from oxidation. For example, in an etching process in which the first electrode EL1 is patterned, a silver component included in the layer of the first electrode EL1 may also be prevented from being reduced to be remained as particles causing defects.

In an embodiment, the capping pattern layer CPP and the first electrode EL1 may be provided through the same processes and include the same materials. However, this is an example, and the capping pattern layer CPP may be provided through different processes or include different materials from the first electrode EL1. Embodiments are not limited thereto.

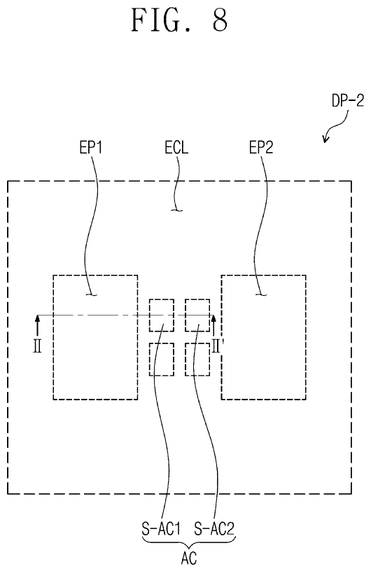

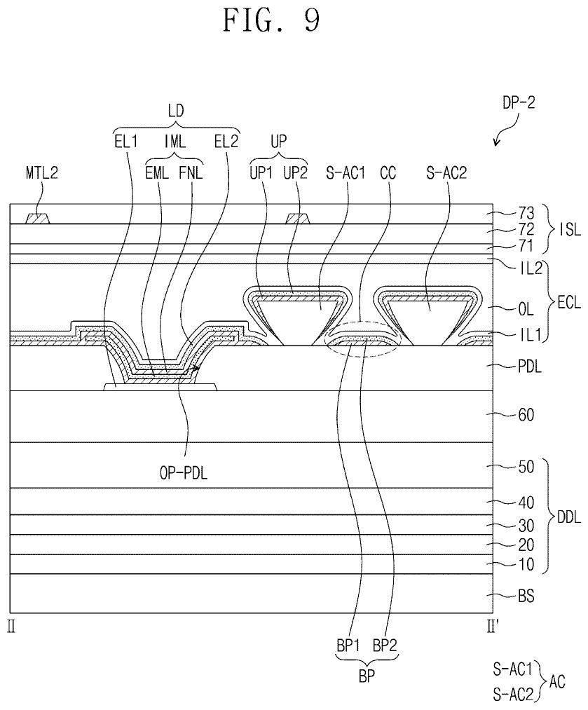

FIG. 8 is an enlarged schematic plan view of a portion of a display panel according to an embodiment. FIG. 9 is a schematic cross-sectional view of a display panel according to an embodiment. FIG. 9 is a schematic cross-sectional view showing a portion corresponding to a line II-II′ shown in FIG. 8.

Referring to FIGS. 8 and 9, the display panel DP-2 according to an embodiment may include light emitting parts EP1 and EP2 and a separator AC disposed between light emitting parts EP1 and EP2. The separator AC may be covered by an encapsulation layer ECL. In FIG. 8, the first light emitting part EP1, the second light emitting part EP2, and the separator AC is shown in dashed lines, and this means that they are disposed under the encapsulation layer ECL.

The separator AC may include a first sub-separator S-AC1 and a second sub-separator S-AC2. Each of the first sub-separator S-AC1 and the second sub-separator S-AC2 may have the shape that the width decreases as being closer to the surface adjacent to the pixel definition layer PDL. For example, each of the first sub-separator S-AC1 and the second sub-separator S-AC2 may have an inverse taper shape.

The first sub-separator S-AC1 may be adjacent to the first light emitting part EP1, and the second sub-separator S-AC2 may be adjacent to the second light emitting part EP2. The encapsulation layer ECL may cover each of the first sub-separator S-AC1 and the second sub-separator S-AC2.

In an embodiment, each of the first sub-separator S-AC1 and the second sub-separator S-AC2 may include a base resin and a scattering agent. The base resin may include at least one of a novolac-based resin and an epoxy-based resin. The scattering agent may include at least one of TiO₂, ZnO, Al₂O₃, SiO₂, and hollow silica. For example, the scattering agent may include TiO₂. The separator AC may include about 1 wt % to about 15 wt % of the scattering agent, based on the total weight of the separator AC. For example, the separator AC may include 8 wt % to 11 wt % of the scattering agent, based on the total weight of the separator AC. The function of the scattering agent will be described in the description of the manufacturing method of the display panel.

The encapsulation layer ECL may include a first inorganic layer IL1 adjacent to the second electrode EL2, a second inorganic layer IL2 disposed on the first inorganic layer IL1, and an organic layer OL disposed between the first inorganic layer IL1 and the second inorganic layer IL2. The first inorganic layer IL1 may have the shape following the first sub-separator S-AC1 and the second sub-separator S-AC2. The first inorganic layer IL1 may extend to cover the first sub-separator S-AC1 and the second sub-separator S-AC2. The first inorganic layer IL1 may extend along an upper surface and side surfaces of the first sub-separator S-AC1 and the second sub-separator S-AC2.

The organic layer OL may fill (or may be disposed) between the first sub-separator S-AC1 and the second sub-separator S-AC2. Referring to a portion CC in FIG. 9, the organic layer OL may be fixed to each of the shape following the first sub-separator S-AC1 and the second sub-separator S-AC2 each having the inverse taper shape. For example, since each of the first sub-separator S-AC1 and the second sub-separator S-AC2 has the inverse taper shape, the adhesion of the organic layer OL to the first sub-separator S-AC1 and the adhesion of the organic layer OL to the second sub-separator S-AC2 may increase. Accordingly, delamination of the encapsulation layer ECL from the layer including the pixel definition layer PDL and the light emitting element LD may be reduced to improve the reliability of a product.

For example, the display panel DP-2 in an embodiment may further include a bottom dummy layer BP disposed between the first sub-separator S-AC1 and the second sub-separator S-AC2 on the pixel definition layer PDL. The bottom dummy layer BP may be covered by the organic layer OL. The bottom dummy layer BP may include a first bottom dummy layer BP1 and a second bottom dummy layer BP2 on the pixel definition layer PDL. The first bottom dummy layer BP1 and the intermediate layer IML may be formed in the same processes. The second bottom dummy layer BP2 and the second electrode EL2 may be formed in the same processes. For example, the first bottom dummy layer BP1 and the second bottom dummy layer BP2 may be formed in the manufacturing processes of the intermediate layer IML and the second electrode EL2, respectively. In another example, the bottom dummy layer BP may be omitted.

For example, the display panel DP-2 according to an embodiment may further include an upper dummy layer UP disposed on the top of the separator AC. The upper dummy layer UP may include a first upper dummy layer UP1 disposed on the separator AC and a second upper dummy layer UP2 disposed on the first upper dummy layer UP1. The first upper dummy layer UP1 and the intermediate layer IML may be formed in the same processes. The second upper dummy layer UP2 and the second electrode EL2 may be formed in the same processes. For example, the first upper dummy layer UP1 and the second upper dummy layer UP2 may be formed in the manufacturing processes of the intermediate layer IML and the second electrode EL2, respectively. In an embodiment, the upper dummy layer UP may be omitted.

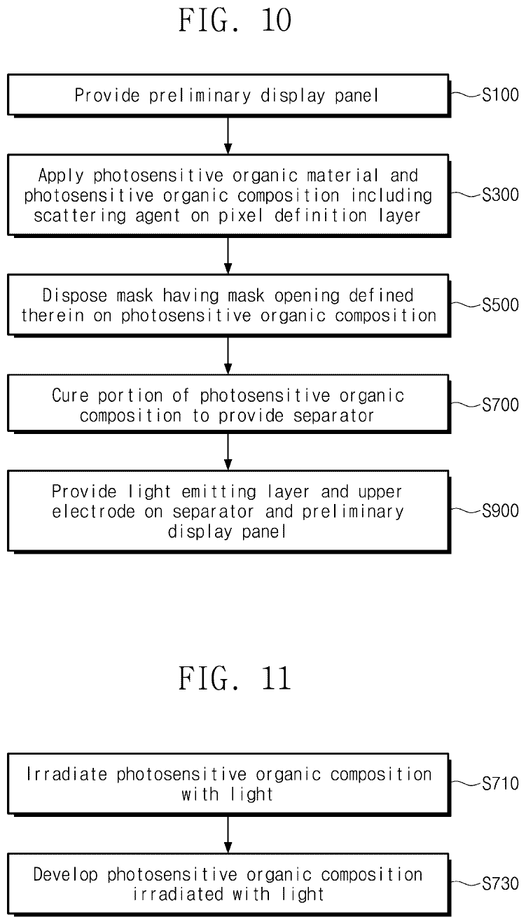

Hereinafter, referring to FIGS. 10 to 13D, a manufacturing method of a display panel will be described. For example, the descriptions about the structural feature of the display panel described with reference to FIGS. 1 to 9 are omitted, and only the feature of the manufacturing the display panel will be described for descriptive convenience. For example, the description will be provided based on the structure of the separator described with reference to FIGS. 1 to 7, and a separator manufacturing method to be described with reference to FIGS. 10 to 13D may be applied to the separator in FIGS. 8 and 9.

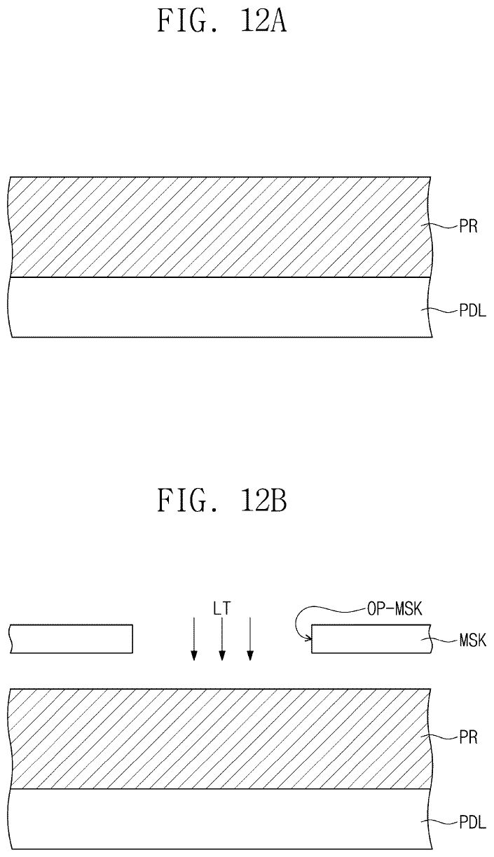

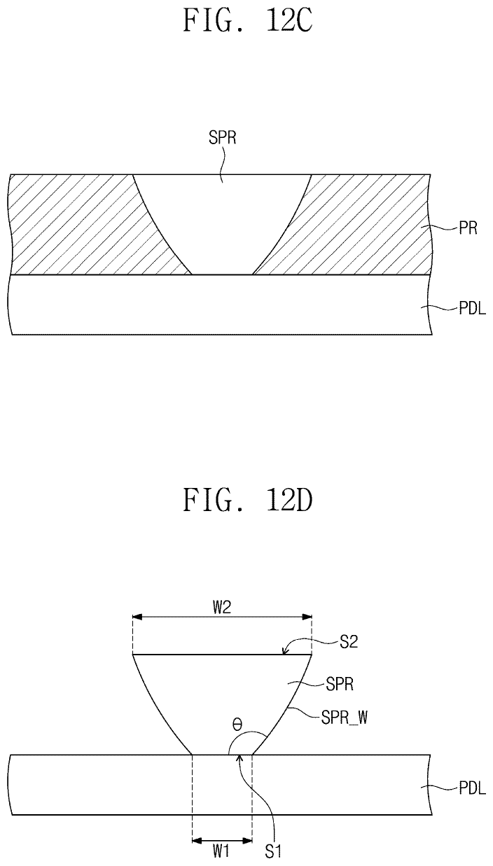

FIG. 10 is a flowchart of a manufacturing method of a display panel according to an embodiment. FIG. 11 is a flowchart showing a step of the manufacturing method of a display panel according to an embodiment. FIG. 12A schematically shows a step of a manufacturing method of a display panel according to an embodiment. FIG. 12B schematically shows a step of the manufacturing method of a display panel according to an embodiment. FIG. 12C schematically shows a step of the manufacturing method of a display panel according to an embodiment. FIG. 12D schematically shows a step of the manufacturing method of a display panel according to an embodiment.

Referring to FIG. 10, the manufacturing method of a display panel may include a step (S100) for providing a preliminary display panel, a step (S300) for applying a photosensitive organic composition including a base resin and a scattering agent on a pixel definition layer, a step (S500) for disposing a mask having a mask opening defined therein on the photosensitive organic composition, a step (S700) for curing a portion of the photosensitive organic composition to provide a separator, and a step (S900) for providing a light emitting layer and an upper electrode on the separator and the preliminary display device.

Referring to FIG. 11, the step for curing a portion of the photosensitive organic composition to provide a separator may include a step (S710) for irradiating the photosensitive organic composition with light, and a step (S730) for developing the photosensitive organic composition irradiated with light. For example, the step for curing a portion of the photosensitive organic composition to provide a separator may not include a step for heating the photosensitive organic composition irradiated with light between the step (S710) for irradiating the photosensitive organic composition with light, and the step (S730) for developing the photosensitive organic composition irradiated with light. Accordingly, the manufacturing method of a display panel according to an embodiment may have simplified processes.

FIG. 12A schematically shows the step for applying, on the pixel definition layer, a photosensitive organic composition including a base resin and a scattering agent. Referring to FIG. 12A, the manufacturing method of a display panel according to an embodiment may include applying the photosensitive organic composition PR on the pixel definition layer PDL. In an embodiment, the step for applying the photosensitive organic composition PR on the pixel definition layer PDL may include applying the photosensitive organic composition PR to cover a portion of the pixel definition layer PDL.

The photosensitive organic composition PR may include the base resin and the scattering agent. The photosensitive organic composition PR may include the base resin to absorb light to be cured. The photosensitive base resin may include at least one of a novolac-based resin, an acrylic-based resin, and an epoxy-based resin. The photosensitive organic composition PR may include the scattering agent so that the energy of light irradiated to the photosensitive organic composition PR may be dispersed on the photosensitive organic composition PR. The photosensitive organic composition PR may include about 1 wt % to about 15 wt % of the scattering agent, based on the total weight of the photosensitive organic composition PR. In case that the photosensitive organic composition PR includes less than about 1 wt % of the scattering agent, it is difficult to provide a pattern. The photosensitive organic composition PR may include greater than about 15% of the scattering agent, the light may be excessively scattered to increase an exposure amount for curing the photosensitive organic composition PR.

For example, the photosensitive organic composition PR may include about 8 wt % to about 11 wt % of the scattering agent, based on the total weight of the photosensitive organic composition PR.

The scattering agent may include at least one of TiO₂, ZnO, Al₂O₃, SiO₂, hollow silica, or polystyrene particles. The scattering agent may include at least one of TiO₂, ZnO, Al₂O₃, SiO₂, hollow silica, and polystyrene particles, or a mixture of two or more kinds of materials selected from among TiO₂, ZnO, Al₂O₃, SiO₂, hollow silica, and polystyrene particles composed of polystyrene resin.

The photosensitive organic composition PR may further include at least one of a photosensitive compound, a coupling agent, a crosslinker, a solvent, and a surfactant. The photosensitive compound may absorb light to induce curing the photosensitive organic composition PR. The photosensitive compound may include at least one of a photo active compound(PAC) and a photo acid generator(PAG).

For example, the photosensitive compound may include at least one of a diazonaphthoquinone derivative, a diazide derivative, a benzophenone derivative, a triazine derivative, or a sulfonium derivative. For example, the photosensitive compound may include at least one of the following compounds. For example, the photo acid generator may at least one of 4-methoxyphenylphenyl iodonium trifluoromethanesulfonate, bis (4-tert-butylphenyl) iodonium trifluoromethanesulfonate, triphenylsulfonium trifluoromethanesulfonate, tri(4-methylphenyl)sulfonium trifluoromethanesulfonat, 2,4,6-trimethylphenyldiphenylsulfonium trifluoromethanesulfonate, 1-(2-naphthoylmethyl)thiolaniumtrifluoromethanesulfonate, 4-hydroxy-1-naphthyldimethylsulfonium trifluoromethanesulfonate, cyclohexylmethyl(2-oxocyclohexyl)sulfonium trifluoromethanesulfonate, 2-methyl-4,6-bis-(trichloromethyl)-

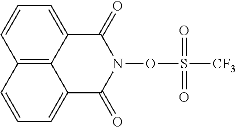 [SMILES: O=C1c2cccc3cccc(c23)C(=O)N1OS(=O)(=O)C(F)(F)F]

1,3,5-triazine. 2,4,6-tris(trichloromethyl)-1,3,5-triazine, 2-phenyl-4,6-bis(trichloromethyl)-1,3,5-triazine, 2-(4-methoxyphenyl)-4,6-bis(trichloromethyl)-1,3,5-triazine, 2-(4-methoxystyryl)-4,6-bis(trichloromethyl)-1,3,5-triazine, 2-(2,4-dimethoxystyryl)-4,6-bis(trichloromethyl)-1,3,5-triazine, 2-(4-methoxystyryl)-4,6-bis(trichloromethyl)-1,3,5-triazine, 1-benzoyl-1-phenylmethyl p-toluenesulfonate, 2-benzoyl-2-hydroxy-2-phenylethyl p-toluenesulfonate, 1,2,3-benzene-triyl-tris(methanesulfonate), 2-dinitrobenzyl p-toluenesulfonate, and 4-nitrobenzyl p-toluenesulfonate. The photosensitive compound may include at least one of the following compounds expressed as Chemical formulas (1) and (2). This is an example, and embodiments are not limited thereto.

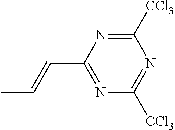

The coupling agent may include a silane coupling agent. For example, the coupling agent may include at least one of (3-glycidoxypropyl) trimethoxysilane, (3-glycidoxypropyl) triethoxysilane, (3-glycidoxypropyl) methyldimethoxysilane, (3-glycidoxypropyl) methyldiethoxysilane, (3-glycidoxypropyl) dimethylethoxysilane, 3,4-epoxybutyltrimethoxysilane, 3,4-epoxybutyltriethoxysilane, 4-epoxycyclohexyl) ethyltriethoxysilane, ethyltrimethoxysilane, 2-(3,4-epoxycyclohexyl) aminopropyltrimethoxysilane, aminopropyltriethoxysilane, 3-triethoxysil-N-(1,3

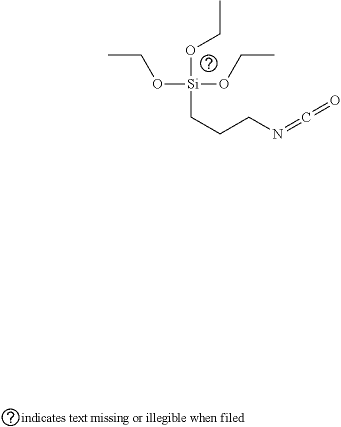 [SMILES: CCO[Si](CCCN=C=O)(OCC)OCC]

dimethylbutylidene) propylamine, N-2(aminoethyl)3-aminopropyltrimethoxysilane), N-2(aminoethyl)3-aminopropyltriethoxysilane), N-2(aminoethyl-3-aminopropyl methyldimethoxysilane), N-phenyl-3-aminopropyltrimethoxysilane, and (3-isocyanatepropyl)triethoxysilane. For example, the coupling agent may include the following compound expressed as Chemical formula (3). This is an example, and embodiments are not limited thereto.

The crosslinker may crosslink the base resin. For example, the crosslinker may include a melamine-based compound. The melamine-based compound may include at least one of hexamethylmelamine, hexamethylolmelamine hexamethyl ether, and hexabutoxymethylmelamine.

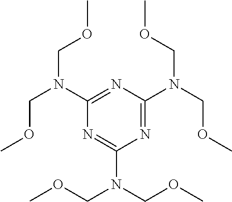

For example, the crosslinker may include the following compound expressed as Chemical formula (4). This is an example and embodiments are not limited thereto.

The solvent may include materials having compatibility with a base resin, a scattering agent but not reacting with the base resin, the scattering agent. For example, the solvent may include at least one of propylene glycol methyl ether acetate (PGMEA), ethyl lactate, ethyl cellosolve acetate (ECA), 2-methoxyethyl acetate, gamma-butyrolactone (GBL), methyl methoxy propionate (MMP), ethyl beta-ethoxypropionate (EEP), propyleneglycol monomethylether (PGME), N-propyl acetate (nPAC), and n-butyl acetate (nBA).

The surfactant may be used to improve the applicability or the developing properties of the photosensitive organic composition. The surfactant may include at least one of a silicon-based surfactant and a fluorine-based surfactant. This is an example, and embodiments are not limited thereto.

FIGS. 12B and 12C show the step for disposing a mask in which a mask opening is formed in the photosensitive organic composition, and the step for curing a portion of the photosensitive organic composition. FIG. 12D shows the step for developing the photosensitive organic composition irradiated with light.

Referring to FIGS. 12B to 12D, the manufacturing method of a display panel according to an embodiment may include a step for disposing the mask MSK in which the mask opening OP-MSK is formed on the applied photosensitive organic composition PR. Light LT may be irradiated on the photosensitive organic composition PR through the mask opening OP-MSK. For example, a portion irradiated with the light LT on the photosensitive organic composition PR may be determined according to the shape and area of the mask opening OP-MSK.

For example, the portion irradiated with the light LT on the photosensitive organic composition PR may be cured. For example, the photosensitive organic composition PR may be an organic layer that is cured by being irradiated with light. Accordingly, the separator SPR may be formed in correspondence to the shape and area of the mask opening OP-MSK of the mask MSK disposed on the photosensitive organic composition PR.

The provided separator SPR may include a first surface S1 adjacent to the pixel definition layer PDL and a second surface S2 facing the first surface S1. The width W1 of the first surface S1 in a direction may be smaller than the width W2 of the second surface S2 in the direction. The width of the separator SPR according to an embodiment may decrease as being closer to the first surface S1 from the second surface S2. For example, the separator SPR may have an inverse taper shape. For example, an inner angle (θ, hereinafter, a taper angle) of an outer surface SPR_W of the separator SPR to the top surface (or upper surface) of the pixel definition layer PDL may be an obtuse angle. However, this is an example, and in case that the separator SPR disconnects a deposition layer such as the intermediate layer IML (see FIG. 5) or the second electrode EL2 (see FIG. 5), the taper angle (θ) may be set in various ways, but embodiments are not limited thereto.

The exposure amount of the light LT irradiated on the photosensitive organic composition PR may be about 20 mJ/cm² to about 200 mJ/cm². For example, the exposure amount of the light LT irradiated on the photosensitive organic composition PR may be about 80 mJ/cm² to about 120 mJ/cm². The photosensitive organic composition PR including no scattering agent does not provide the inverse taper shape well, as the exposure amount of the light LT increases. For example, as the exposure amount of the light LT decreases, the photosensitive organic composition PR including no scattering agent provides the inverse taper shape well, but the degree of cure is small. Then, the photosensitive organic composition PR is prone to be detached from the pixel definition layer PDL to reduce the reliability.

The photosensitive organic composition PR according to an embodiment may include the scattering agent, and thus may have the inverse taper shape and an excellent degree of cure, in case that the light LT with a relatively large exposure amount is irradiated. For example, by including the scattering agent, the photosensitive organic composition PR according to an embodiment may provide the separator SPR having a reliable inverse taper shape. For example, the photosensitive organic composition PR may include about 1 wt % to about 15 wt % of the scattering agent, based on the total weight of the photosensitive organic composition PR. For example, the photosensitive organic composition PR may provide the separator SPR having the reliable inverse taper shape by including about 8 wt % to about 11 wt % of the scattering agent, based on the total weight of the photosensitive organic composition PR.

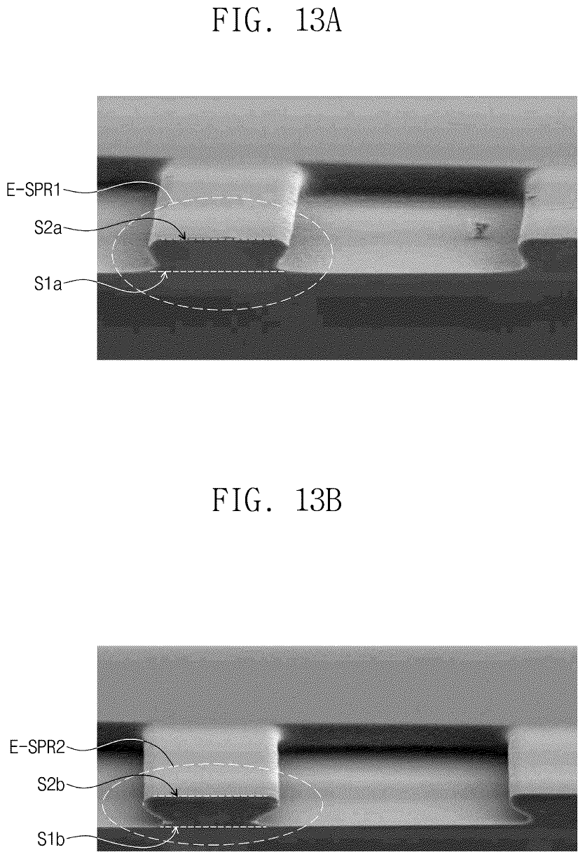

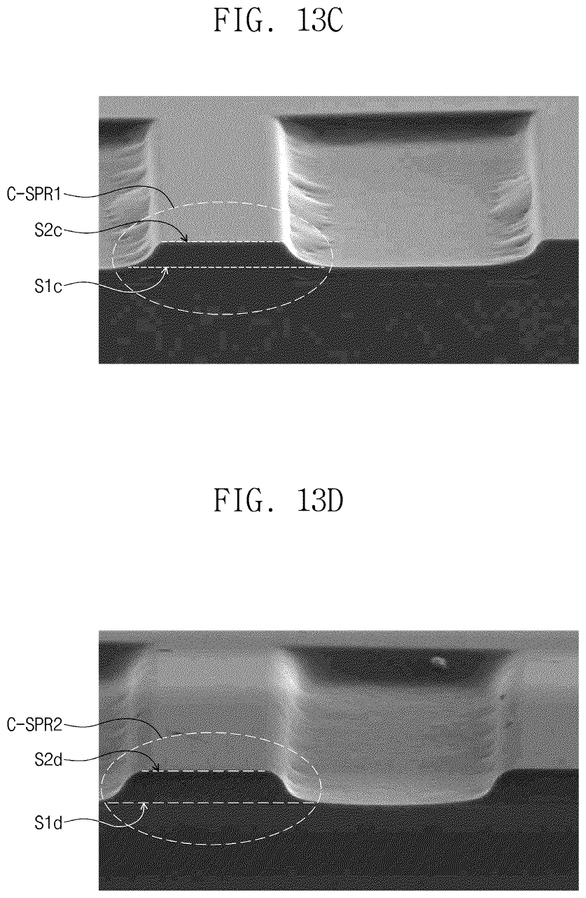

FIG. 13A shows the shape of a separator according to an embodiment. FIG. 13B shows the shape of a separator according to an embodiment. FIG. 13C shows the shape of a separator according to a comparative example. FIG. 13D shows the shape of a separator according to a comparative example. The separators shown in FIGS. 13A to 13D are manufactured by the display panel manufacturing method in FIGS. 10 to 12D.

FIG. 13A is the separator formed of the photosensitive organic composition including about 8 wt % of the scattering agent, based on the total weight of the photosensitive organic composition. FIG. 13B is the separator formed of the photosensitive organic composition including about 11 wt % of the scattering agent. FIG. 13C is the separator formed of the photosensitive organic composition including no scattering agent, based on the total weight of the photosensitive organic composition. FIG. 13D is the separator formed of the photosensitive organic composition including about 5 wt % of the scattering agent, based on the total weight of the photosensitive organic composition. In the processes of providing the separator in FIGS. 13A to 13D, the exposure amount of the light irradiated to the photosensitive organic composition may be about 100 mJ/cm².

Referring to FIGS. 13A and 13B, the separators E-SPR1 and E-SPR2 according to an embodiment may have the inverse taper shape with widths of the first surfaces S1a and S1b may be smaller than those of the second surfaces S2a and S2b, respectively. Referring to FIGS. 13C and 13D, the separators C-SPR1 and C-SPR2 according to a comparative example may have the inverse taper shape with widths of the first surfaces S1c and S1d smaller than those of the second surfaces S2c and S2d, respectively. Accordingly, unlike the comparative example, in case that the photosensitive organic composition including about 8 wt % of the scattering agent is used as in the embodiment, it may be confirmed that in case that light with an exposure amount of 100 mJ/cm² is irradiated, the separator having the inverse taper shape may be provided.

It may be confirmed that the display panel according to an embodiment has excellent patterning reliability, because a portion adjacent to the separators E-SPR1 and E-SPR2 has a flat surface. It may be confirmed that the patterning reliability of the display panel according to a comparative panel is not good, because the remaining amount of a photosensitive organic composition is present at the portion adjacent to the separators C-SPR1 and C-SPR2. Accordingly, in case that the photosensitive organic composition including about 8 wt % of the scattering agent is used as in the embodiment, it may be confirmed that in case that light with an exposure amount of about 100 mJ/cm² is irradiated, the separator may be reliably patterned.

The display panel according to an embodiment may include the separator including the scattering agent to improve the reliability.

The manufacturing method of a display panel according to an embodiment may simplify the processes by including a step for irradiating a photosensitive organic composition including a scattering agent with light to provide a separator.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display panel comprising a display area and a peripheral area adjacent to the display area, the display panel comprising:
a base layer;
first and second transistors on the base layer;
an upper insulation layer on the first and second transistors;
a pixel definition layer disposed on the upper insulation layer and comprising an emission opening;
first and second light emitting elements disposed on the upper insulation layer, each of the first and second light emitting elements comprising:
a first electrode disposed in the emission opening,
a second electrode disposed on the first electrode, and
a light emitting layer disposed between the first electrode and the second electrode; and
a separator disposed between the second electrode of the first light emitting element and the second electrode of the second light emitting element, disposed on the pixel definition layer, and comprising a first surface adjacent to the pixel definition layer and a second surface facing the first surface, the separator having a width increasing as being closer to the second surface from the first surface, wherein
the second electrode of the first light emitting element is electrically connected to the first transistor,
the second electrode of the second light emitting element is electrically connected to the second transistor, and
the separator comprises a base resin and a scattering agent.

2. The display panel of claim 1, wherein the scattering agent comprises at least one of TiO₂, ZnO, Al₂O₃, SiO₂, and hollow silica.

3. The display panel of claim 1, wherein the separator comprises the scattering agent having an amount of about 8 wt % to about 11 wt %, based on a total weight of the separator.

4. The display panel of claim 1, further comprising:
a connection line disposed under the upper insulation layer and electrically connecting the first transistor and the second electrode of the first light emitting element.

5. The display panel of claim 4, further comprising:
a lower insulation layer between the first transistor and the connection line,
wherein the first transistor and the connection line are connected through a contact hole passing through the lower insulation layer.

6. The display panel of claim 4, wherein
the connection line comprises:
a first layer;
a second layer disposed on the first layer; and
a third layer disposed on the second layer, the third layer and the first layer comprising a same material,
an edge portion of each of the first and third layers protrudes from an edge portion of the second layer, and
the second electrode of the first light emitting element contacts a side surface of the second layer of the connection line.

7. The display panel of claim 1, further comprising:
a power line receiving a constant voltage and overlapping the peripheral area,
wherein the first electrode is electrically connected to the power line.

8. A display panel comprising:
a base layer;
a pixel definition layer disposed on the base layer and comprising an emission opening;
first and second light emitting elements disposed on an upper insulation layer, each of the first and second light emitting elements comprising:
a first electrode disposed in the emission opening,
a second electrode disposed on the first electrode, and
a light emitting layer disposed between the first electrode and the second electrode;
a separator disposed between the second electrode of the first light emitting element and the second electrode of the second light emitting element, disposed on the pixel definition layer, and comprising a first surface adjacent to the pixel definition layer and a second surface facing the first surface, the separator having a width increasing as being closer to the second surface from the first surface; and
an encapsulation layer covering the separator,
wherein the separator comprises a base resin and a scattering agent.

9. The display panel of claim 8, wherein the scattering agent comprises at least one of TiO₂, ZnO, Al₂O₃, SiO₂, and hollow silica.

10. The display panel of claim 8, wherein
the separator comprises:
a first sub-separator adjacent to the first light emitting element; and
a second sub-separator spaced apart from the first sub-separator and adjacent to the second light emitting element, and
the encapsulation layer covers each of the first sub-separator and the second sub-separator.

11. The display panel of claim 10, wherein the encapsulation layer comprises:
a first inorganic layer adjacent to the second electrode;
a second inorganic layer disposed on the first inorganic layer; and
an organic layer disposed between the first inorganic layer and the second inorganic layer.

12. The display panel of claim 11, wherein
the first inorganic layer extends along a shape of each of the first sub-separator and the second sub-separator, and
the organic layer is disposed between the first sub-separator and the second sub-separator.

13. The display panel of claim 12, further comprising:
a lower dummy layer disposed between the first sub-separator and the second sub-separator, disposed on the pixel definition layer, and covered by the organic layer.

14. A manufacturing method of a display panel comprising:
providing a preliminary display panel comprising:
a base layer,
first and second transistors disposed on the base layer,
an insulation layer disposed on the first and second transistors,
a pixel definition layer disposed on the insulation layer and comprising an opening, and
a first electrode disposed in the opening of the pixel definition layer;
applying a photosensitive organic composition comprising a base resin and a scattering agent on the pixel definition layer;
disposing a mask comprising a mask opening on the photosensitive organic composition;
forming a separator by irradiating light on the photosensitive organic composition through the mask opening to cure a portion of the photosensitive organic composition; and
forming a light emitting layer and a second electrode on the separator and the preliminary display panel,
wherein the second electrode disposed on the separator and the second electrode disposed on the first electrode are separated from each other.

15. The manufacturing method of a display panel of claim 14, wherein the scattering agent comprises at least one of TiO₂, ZnO, Al₂O₃, SiO₂, and hollow silica.

16. The manufacturing method of a display panel of claim 14, wherein the photosensitive organic composition comprises the scattering agent having an amount of about 8 wt % to about 11 wt %, based on a total weight of the photosensitive organic composition.

17. The manufacturing method of a display panel of claim 14, wherein the photosensitive organic composition further comprises at least one of a photosensitive compound, a coupling agent, a crosslinker, a solvent, and a surfactant.

18. The manufacturing method of a display panel of claim 14, wherein
the separator comprises a first surface adjacent to the pixel definition layer and a second surface facing the first surface, and
a width of the separator increases as being closer to the second surface from the first surface.

19. The manufacturing method of a display panel of claim 14, wherein the forming of the separator comprises:
irradiating light on the photosensitive organic composition; and
developing the photosensitive organic composition irradiated with light.

20. The manufacturing method of a display panel of claim 19, wherein the forming of the separator does not comprise heating the photosensitive organic composition irradiated with light between the irradiating of the light on the photosensitive organic composition and the developing of the photosensitive organic composition irradiated with light.
